(19) United States
(12) Patent Application Publication
(10) Pub. No.: US 2024/0116966 A1
(43) Pub. Date: Apr. 11, 2024

(54) BINUCLEAR METAL PLATINUM COMPLEX AND APPLICATION THEREOF

(71) Applicant: GUANGDONG AGLAIA OPTOELECTRONIC MATERIALS CO., LTD, Foshan, Guangdong (CN)

(72) Inventors: Huiyang LI, Foshan (CN); Xinwei WU, Foshan (CN); Lei DAI, Foshan (CN); Lifei CAI, Foshan (CN)

(73) Assignee: GUANGDONG AGLAIA OPTOELECTRONIC MATERIALS CO., LTD, Foshan, Guangdong (CN)

(21) Appl. No.: 18/038,674

(22) PCT Filed: Oct. 24, 2021
(86) PCT No.: PCT/CN2021/125930

§ 371 Date: May 24, 2023

(30) Foreign Application Priority Data
Dec. 14, 2020 (CN) 202011462573.8

(51) Int. Cl. C07F 15/00; H10K 50/11; H10K 50/15; H10K 50/16; H10K 50/17; H10K 85/30

(52) U.S. Cl. CPC C07F 15/0086; H10K 50/11; H10K 50/15; H10K 50/16; H10K 50/171; H10K 85/346

(57) ABSTRACT

The present invention relates to a binuclear metal platinum complex and application thereof. The binuclear metal platinum complex is a compound having a structure of a chemical formula (I). The compound is applied in an organic light-emitting diode, has lower driving voltage and higher luminous efficiency, and can significantly improve the service life of a device, thus having the potential of being applied in the field of display panels. The present invention further provides an organic light-emitting diode including a cathode, an anode, and an organic layer. The organic layer is one or more of a hole injection layer, a hole transport layer, a light-emitting layer, a hole blocking layer, an electron transport layer, and an electron injection layer. At least one of the organic layers includes the compound of the structural formula (I).

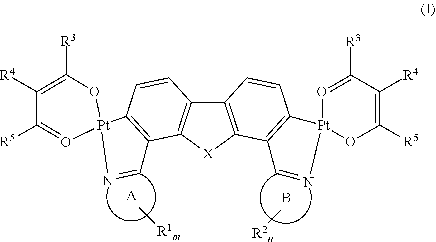

### TECHNICAL FIELD

The present invention relates to the field of luminescent materials, and specifically relates to a binuclear metal platinum complex and application thereof in an organic light-emitting diode.

### BACKGROUND

Organic optoelectronic devices include, but are not limited to, the following categories: organic light-emitting diodes (OLEDs), organic thin film transistors (OTFTs), organic photovoltaic devices (OPVs), light-emitting electrochemical cells (LCEs), and chemical sensors.

In recent years, as a lighting and display technology with a great application prospect, the OLEDs have been widely concerned by the academia and the industry. The OLEDs devices have the characteristics of self-luminous property, wide viewing angle, short reaction time and available flexible devices, thus becoming a strong competitor of next-generation display and lighting technologies. However, the current OLEDs still have the problems of low efficiency, short service life and the like, which need to be further studied.

According to the early fluorescent OLEDs, only singlet luminescence can be used, and triplet excitons generated in the devices cannot be used effectively and are returned to a ground state in a non-radiation manner, so that the popularization and use of the OLEDs are limited. The phenomenon of electrophosphorescence was first reported by ZhiZhiming et al. at the University of Hong Kong in 1998. In the same year, phosphorescent OLEDs were prepared by Thompson et al. with transition metal complexes as luminescent materials. The phosphorescent OLEDs can efficiently utilize singlet and triplet excitons for luminescence, and theoretically achieve the internal quantum efficiency of 100%, so that the commercialization process of the OLEDs is promoted to a large extent. The light-emitting color of the OLEDs can be adjusted by means of the structural design of luminescent materials. The OLEDs can include one or more of light-emitting layers to achieve desired spectra. At present, commercial application of green, yellow and red phosphorescent materials has been realized. According to commercial OLEDs displays, blue fluorescence is usually combined with yellow, or green and red phosphorescence to achieve full-color display. Luminescent materials having higher efficiency and longer service life are required urgently in the industry at present. A metal complex luminescent material has been applied in the industry. However, properties, such as luminous efficiency and service life, still need to be further improved.

### SUMMARY

In view of the above problems of the prior art, the present invention provides a series of binuclear metal platinum complex luminescent materials, and the materials have good photoelectric properties and device service life when applied in organic light-emitting diodes.

The present invention further provides an organic light-emitting diode based on a binuclear platinum complex.

A binuclear metal platinum complex is a compound having a structure of a formula (I):

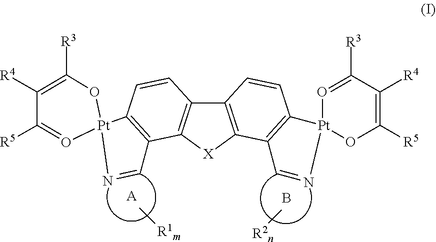

where

each of R¹ to R⁵ is independently selected from hydrogen, deuterium, halogen, amino, carbonyl, carboxyl, thioalkyl, cyano, trimethylsilyl, sulfonyl, phosphino, substituted or unsubstituted alkyl containing 1-20 carbon atoms, substituted or unsubstituted cycloalkyl containing 3-20 ring carbon atoms, substituted or unsubstituted alkenyl containing 2-20 carbon atoms, substituted or unsubstituted alkoxyl containing 1-20 carbon atoms, substituted or unsubstituted aryl containing 6-30 carbon atoms, and substituted or unsubstituted heteroaryl containing 3-30 carbon atoms, or any two adjacent substituents are connected or fused to form a ring, and the heteroaryl includes one or more of N, S, and O heteroatoms;

each of A and B is independently selected from N-containing heteroaromatic rings containing 7-24 carbon atoms; the N-containing heteroaromatic rings include or do not include an S or O heteroatom;

the “substituted” refers to substitution with halogen, amino, cyano, phenyl, or C₁-C₄ alkyl;

m or n is independently 0 to 4;

and X is O or S.

Preferably, each of the R¹ to R⁵ is independently selected from hydrogen, deuterium, halogen, amino, carbonyl, carboxyl, cyano, trimethylsilyl, substituted or unsubstituted alkyl containing 1-6 carbon atoms, substituted or unsubstituted cycloalkyl containing 3-6 ring carbon atoms, substituted or unsubstituted alkenyl containing 2-6 carbon atoms, substituted or unsubstituted alkoxyl containing 1-6 carbon atoms, substituted or unsubstituted aryl containing 6-12 carbon atoms, and substituted or unsubstituted heteroaryl containing 3-6 carbon atoms, or any two adjacent substituents are connected or fused to form a ring, and the heteroaryl includes one or more of N, S, and O heteroatoms;

and the A and the B are a same N-containing heteroaromatic ring.

Preferably, each of the R¹ to R⁵ is independently selected from hydrogen, deuterium, halogen, substituted or unsubstituted C₁-C₆ alkyl, cyano, substituted or unsubstituted cycloalkyl containing 3-6 ring carbon atoms, substituted or unsubstituted aryl containing 6-12 carbon atoms, and substituted or unsubstituted heteroaryl containing 3-6 carbon atoms; the “substituted” refers to substitution with halogen or C₁-C₄ alkyl;

and the A and the B are selected from some of the following structures:

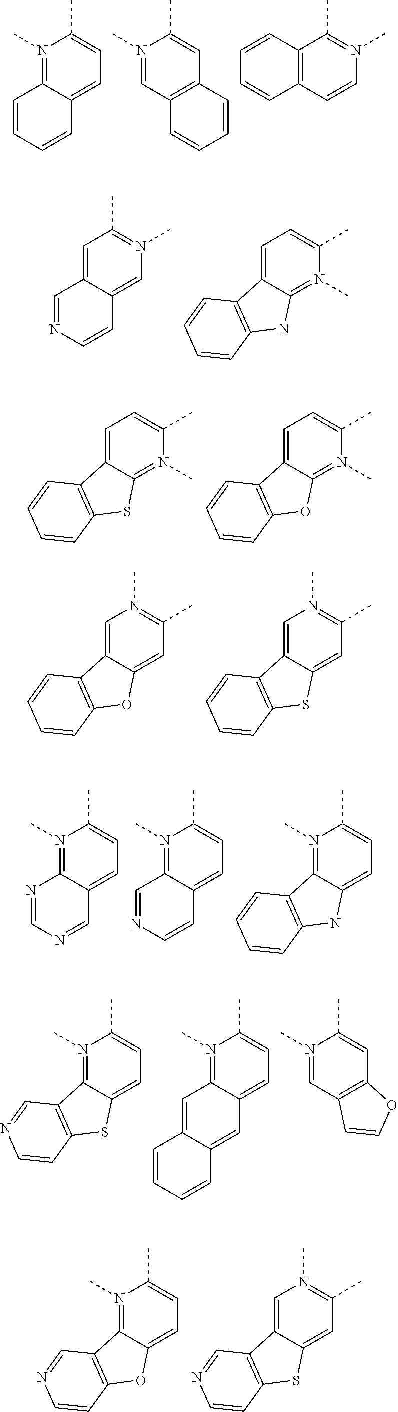

Preferably, each of R¹ to R² is independently selected from hydrogen, deuterium, halogen, substituted or unsubstituted C₁-C₆ alkyl, cyano, substituted or unsubstituted cycloalkyl containing 3-6 ring carbon atoms, and substituted or unsubstituted aryl containing 6-12 carbon atoms; each of R³ to R⁵ is independently selected from hydrogen, deuterium, C₁-C₆ alkyl, and substituted or unsubstituted cycloalkyl containing 3 -6 ring carbon atoms; and the “substituted” refers to substitution with a fluorine atom or C₁-C₄ alkyl.

Preferably, each of the R¹ to R² is independently selected from hydrogen, deuterium, methyl, ethyl, isopropyl, isobutyl, tert-butyl, 3-substituted pentyl, cyano, substituted or unsubstituted cyclopentyl, substituted or unsubstituted cyclohexyl, and substituted or unsubstituted phenyl; and each of the R³ to R⁵ is independently selected from hydrogen, deuterium, methyl, ethyl, isopropyl, isobutyl, tert-butyl, pentyl, 3-substituted pentyl, and cyano.

Each of the R¹ to R² is independently selected from hydrogen, deuterium, methyl, isopropyl, isobutyl, tert-butyl, 3-substituted pentyl, cyano, cyclopentyl, cyclohexyl, and phenyl; and each of the R³ to R⁵ is independently selected from hydrogen, deuterium, methyl, pentyl, and 3-substituted pentyl.

Further preferably, in the general formula (I), R⁴ is hydrogen.

Examples of the platinum metal complex of the present invention are listed below, but are not limited to the structures listed:

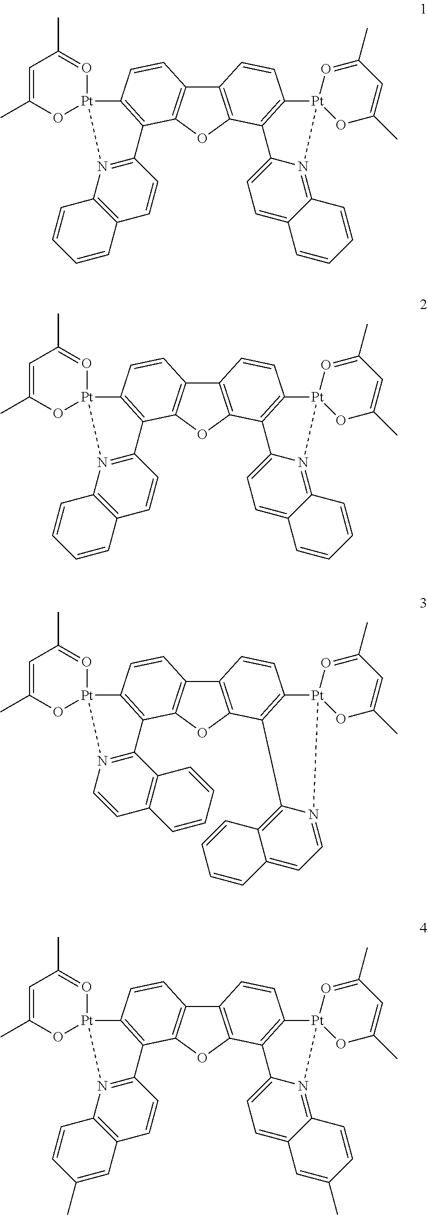

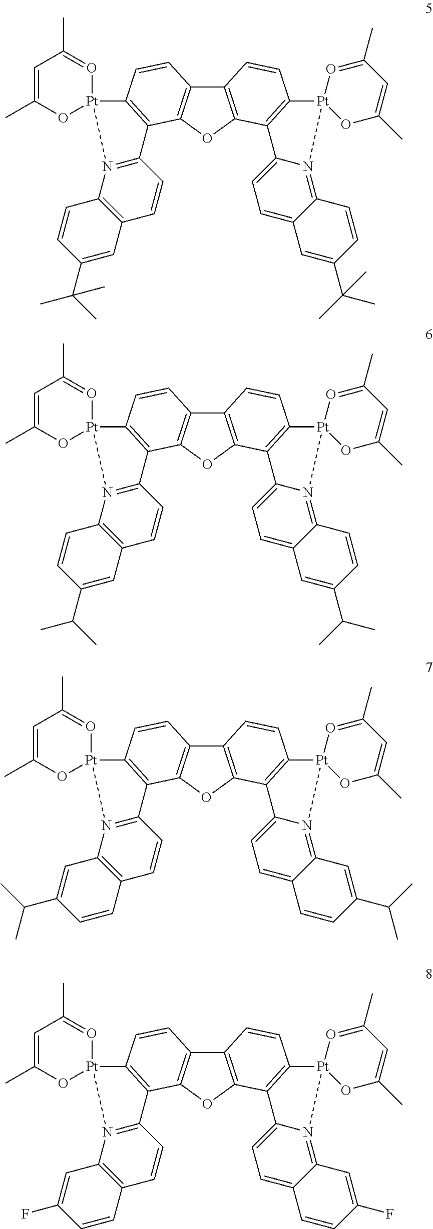

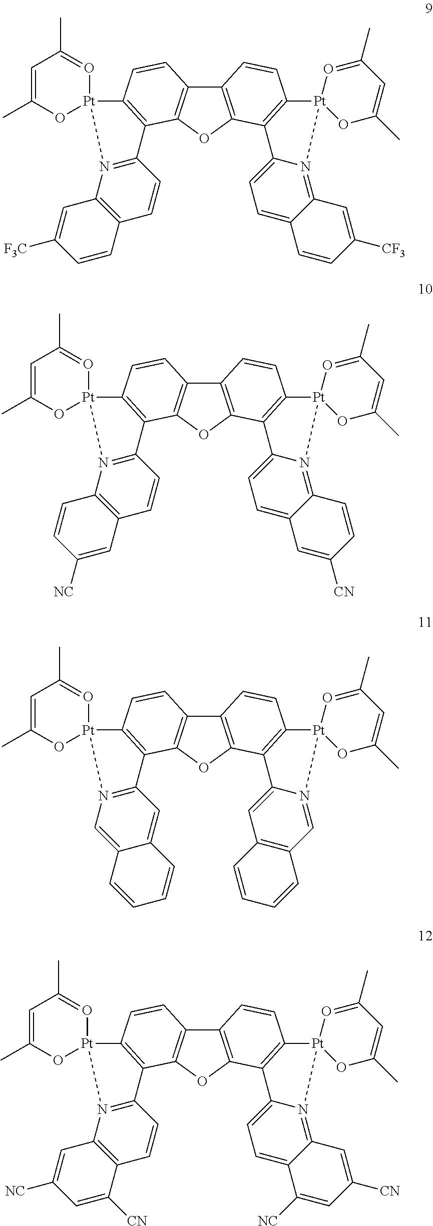

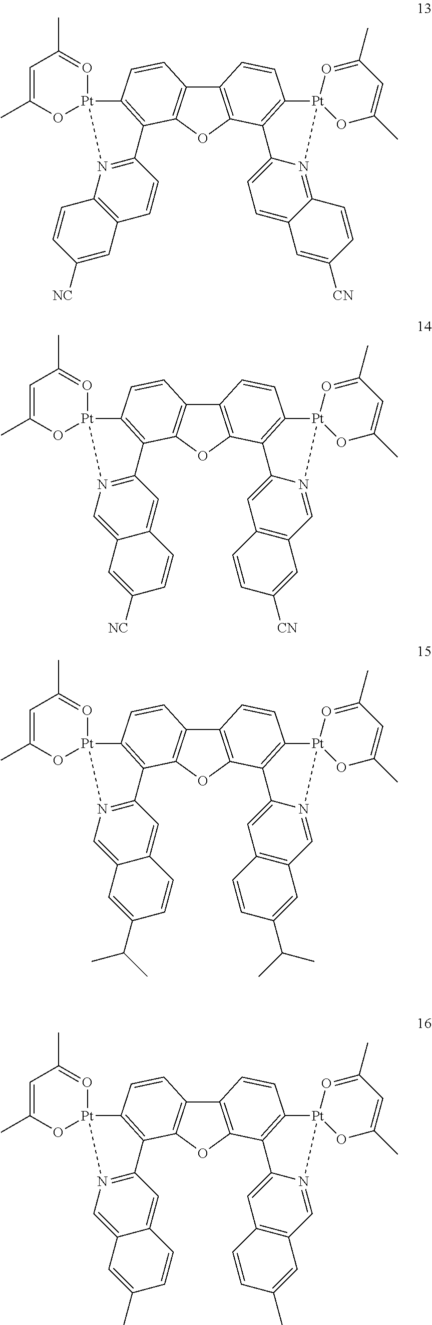

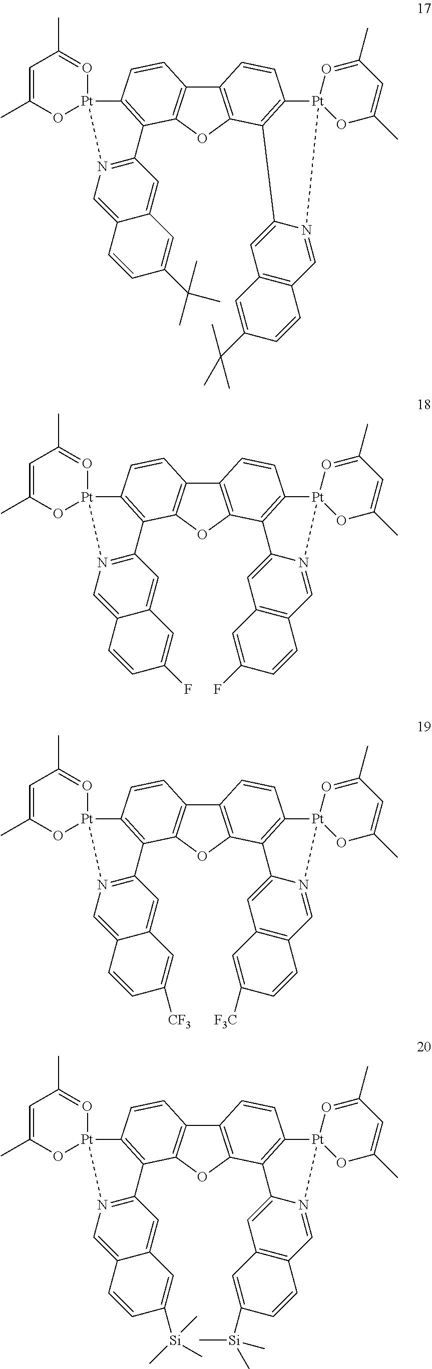

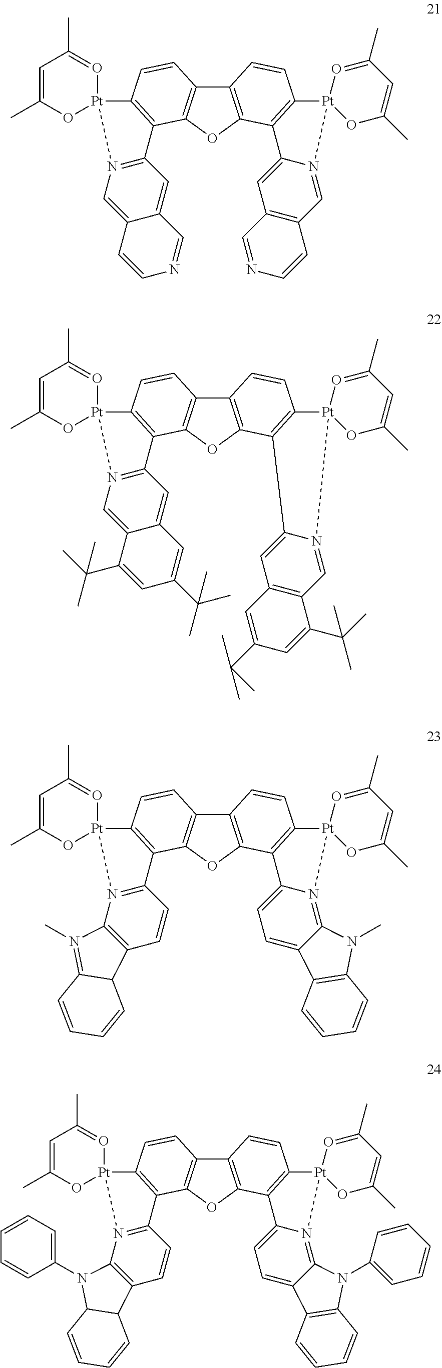

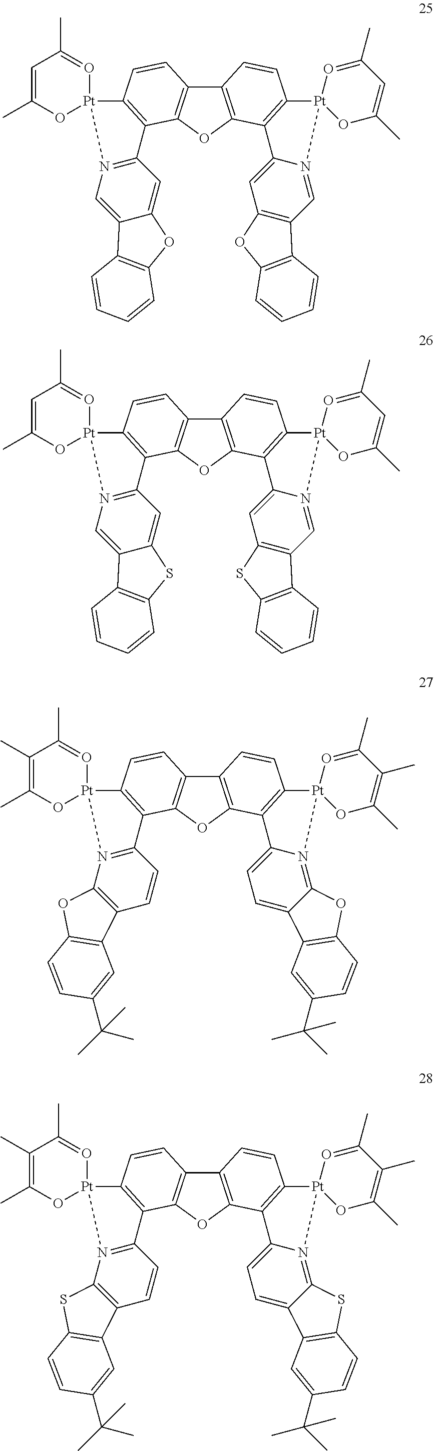

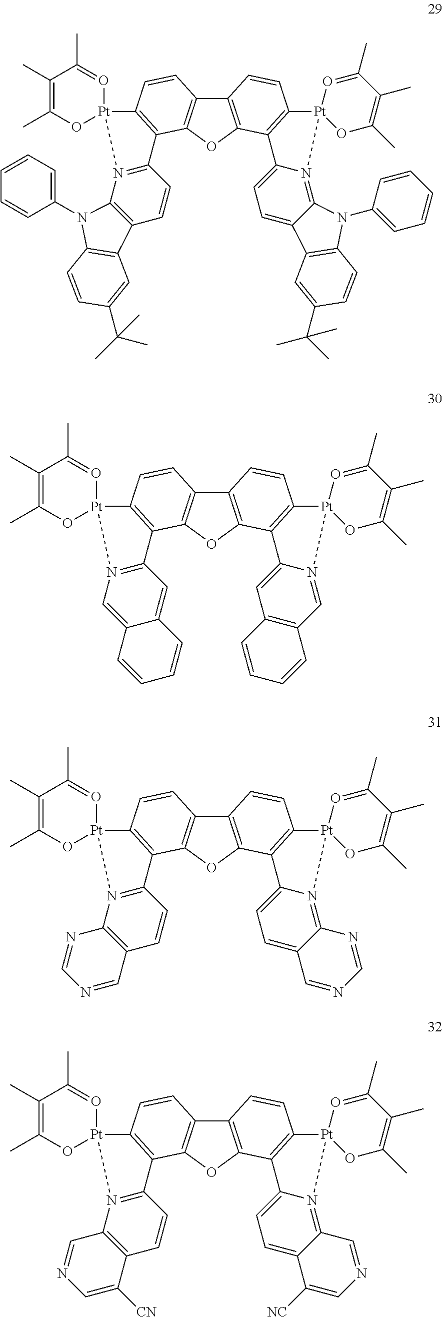

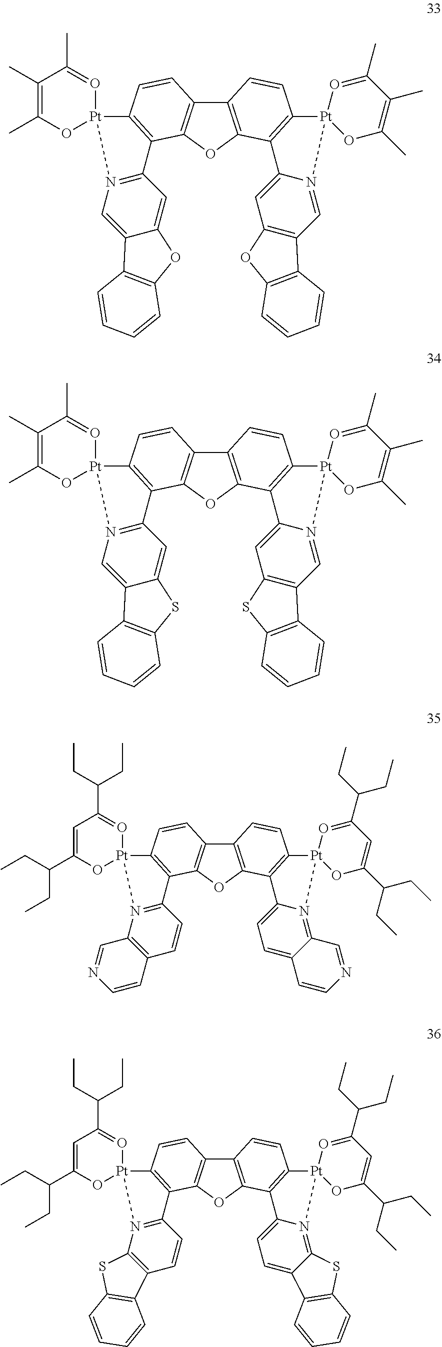

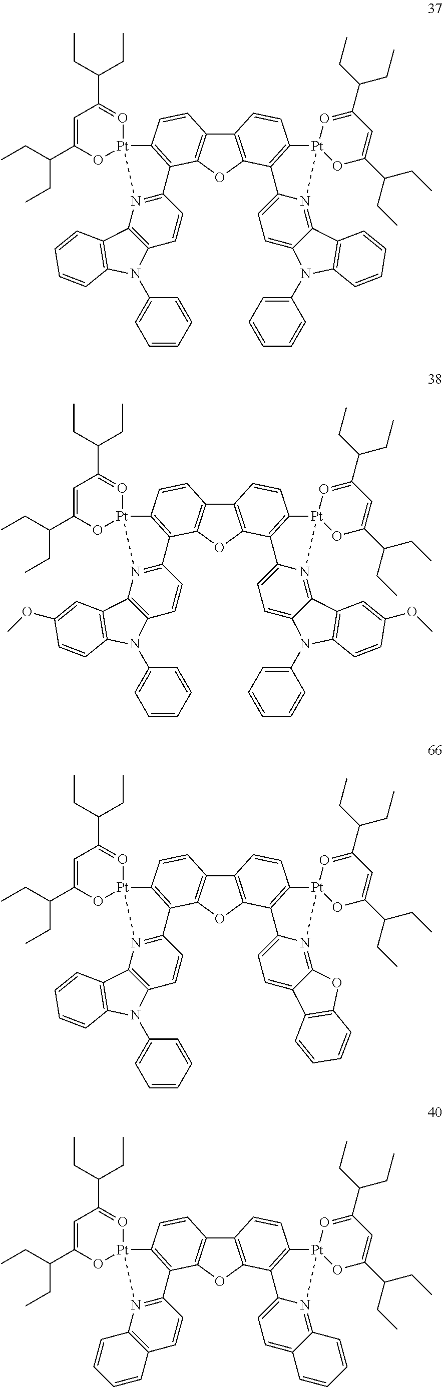

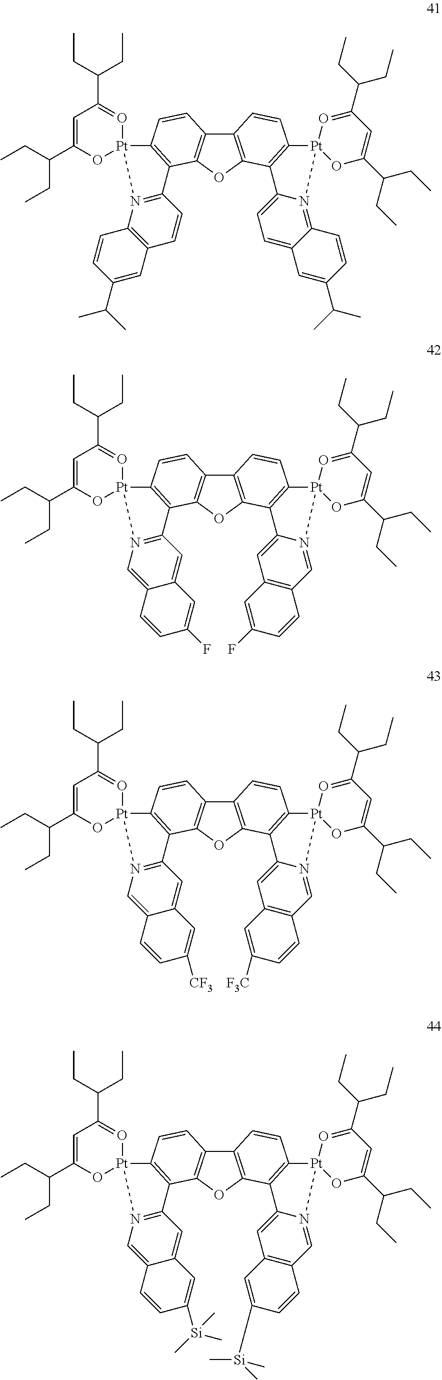

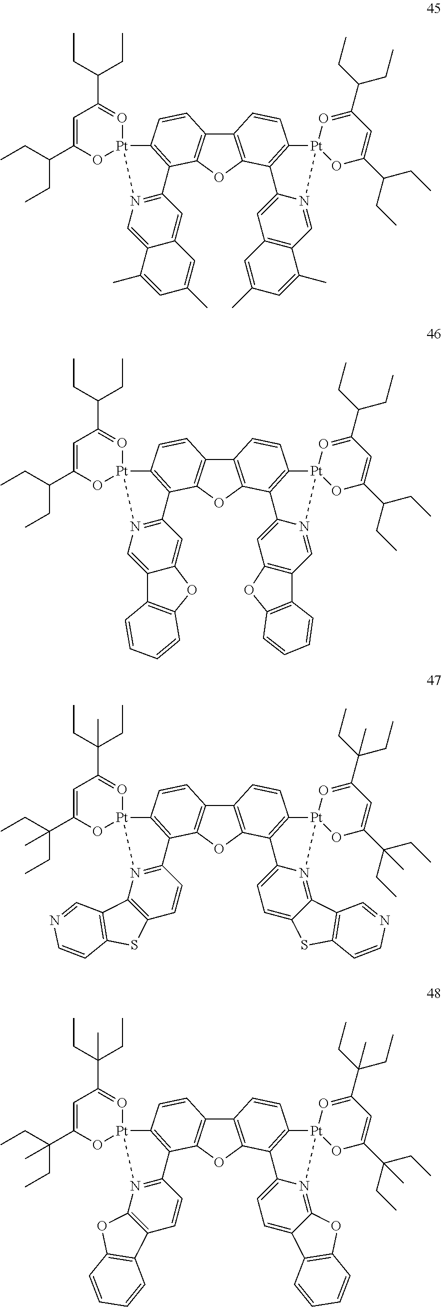

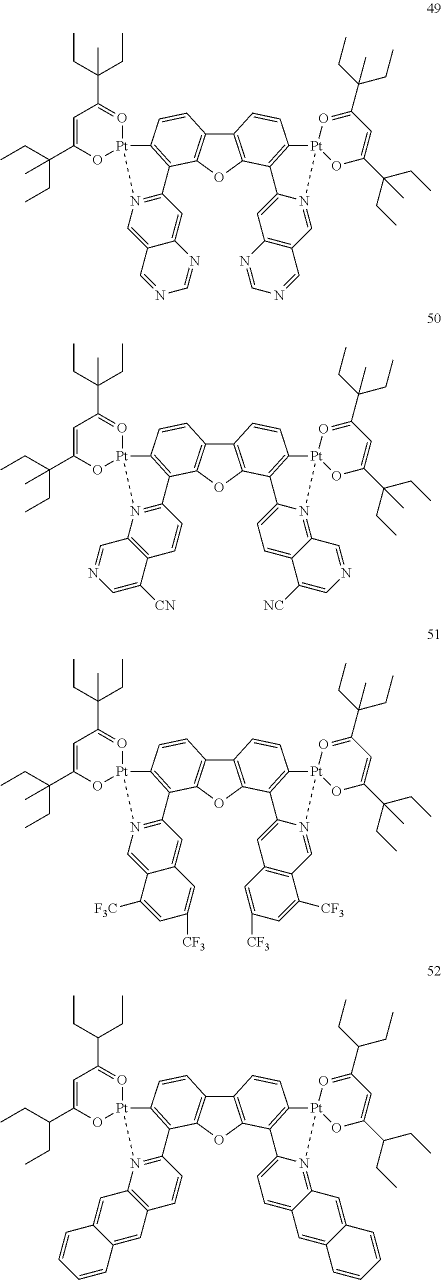

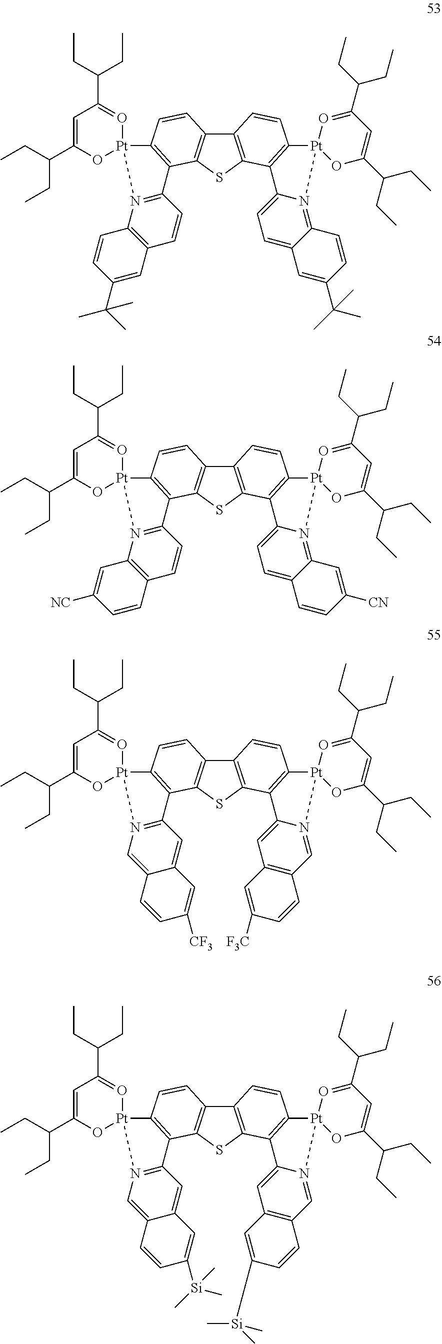

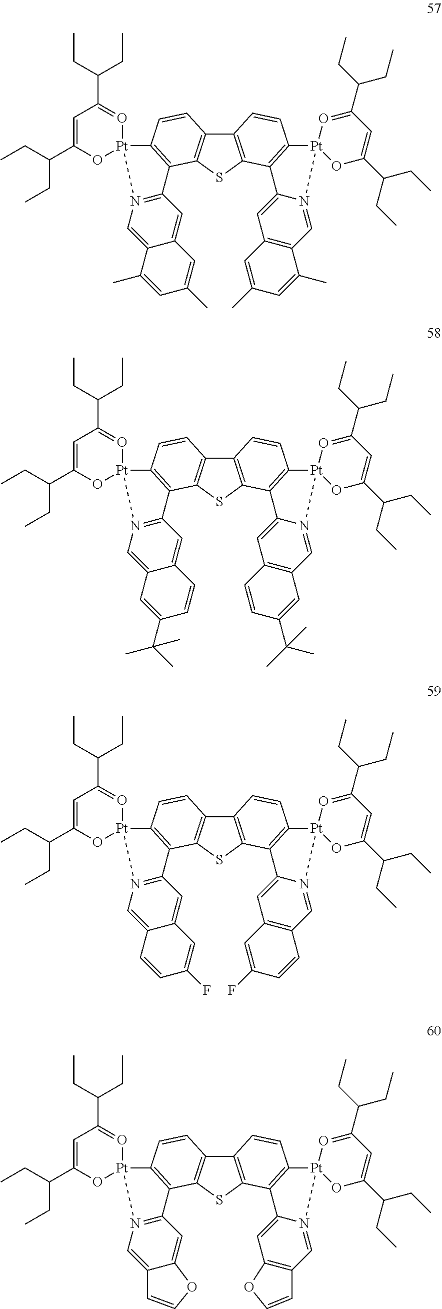

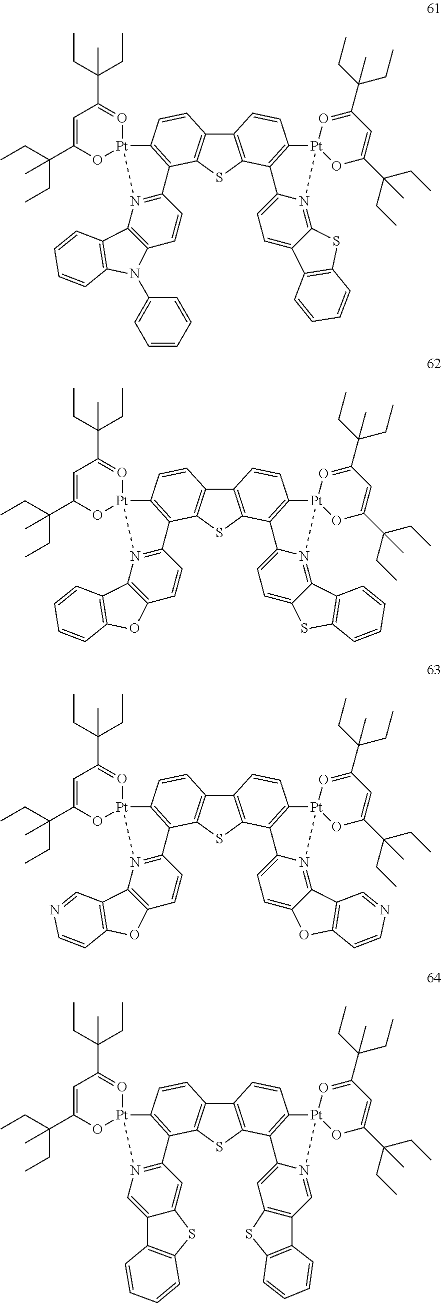

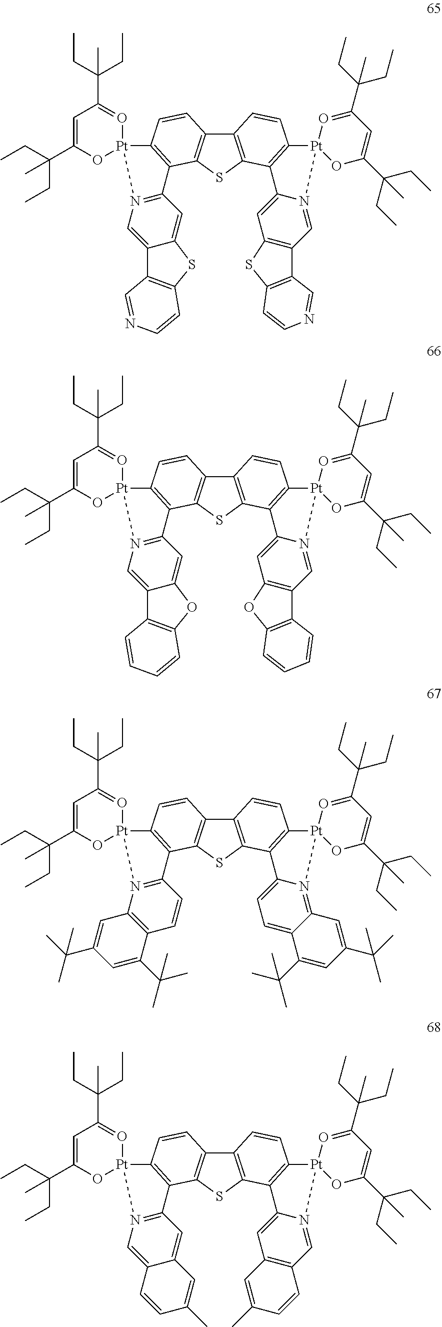

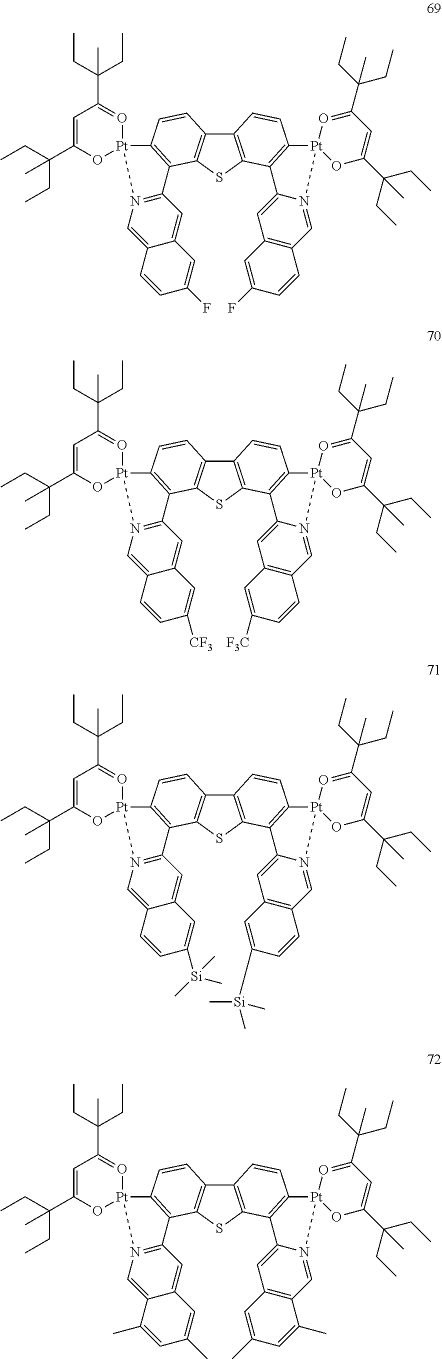

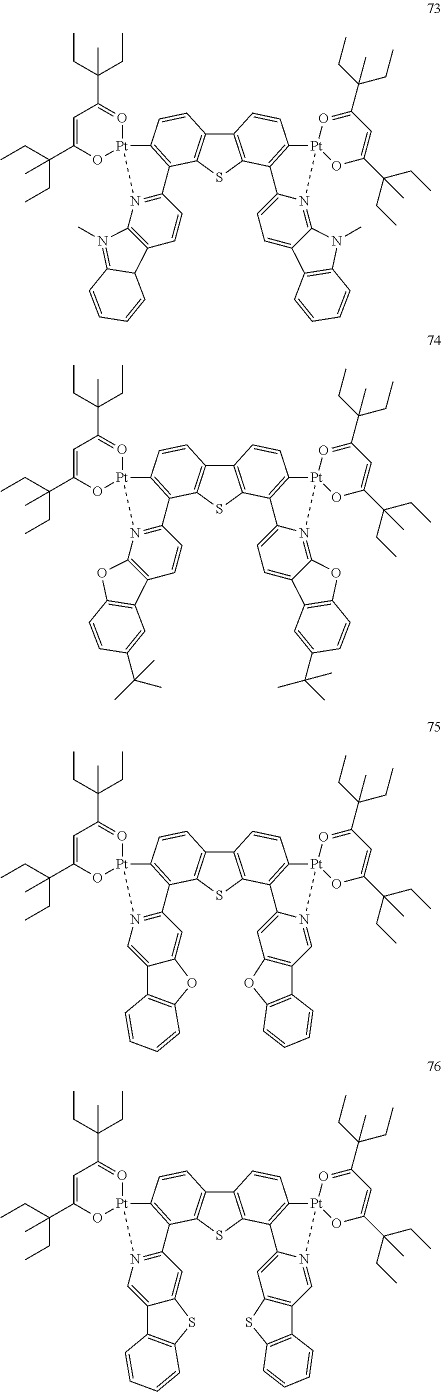

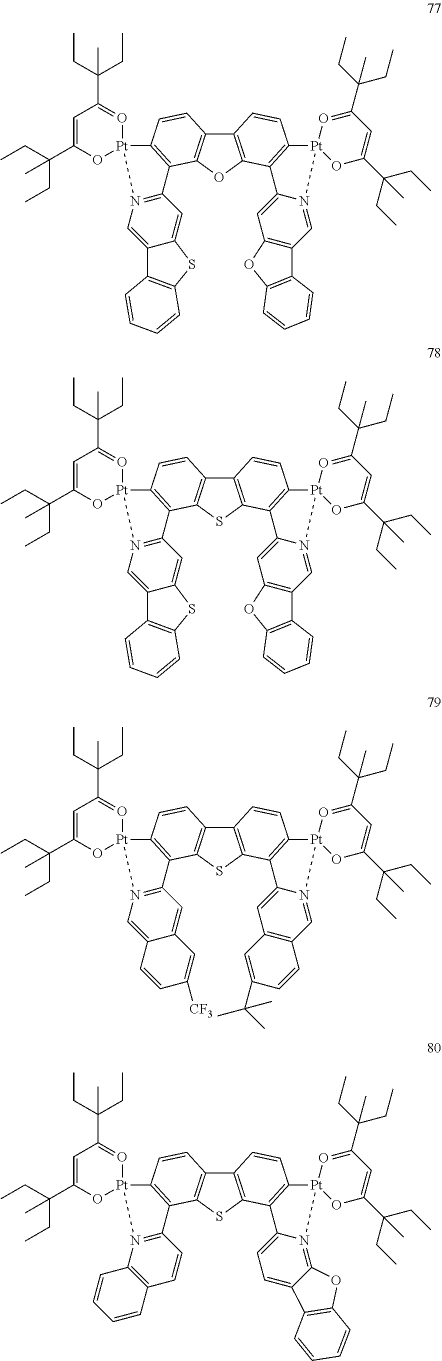

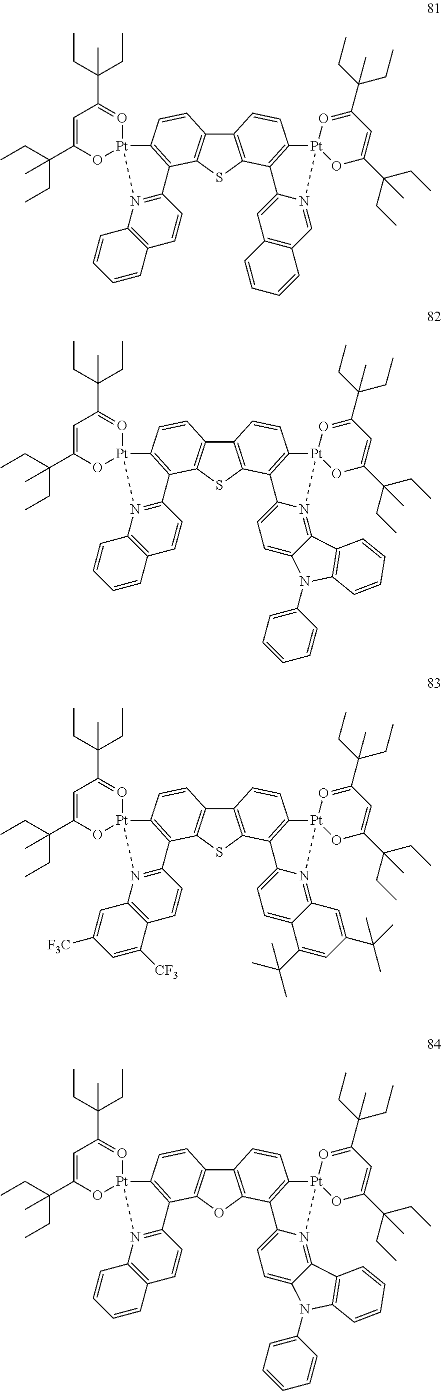

A precursor, namely ligand, of the metal complex has the following structural formula:

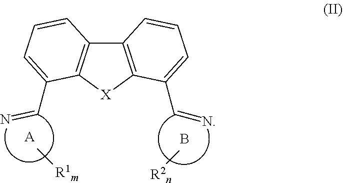

The present invention further provides application of the platinum complex in organic optoelectronic devices. The optoelectronic devices include, but are not limited to, organic light-emitting diodes (OLEDs), organic thin film transistors (OTFTs), organic photovoltaic devices (OPVs), light-emitting electrochemical cells (LCEs), and chemical sensors, preferably OLEDs.

An organic light-emitting diode (OLED) including the platinum complex is provided. The platinum complex is used as a luminescent material in light-emitting devices.

The organic light-emitting diode of the present invention includes a cathode, an anode, and an organic layer, the organic layer is one or more of a hole injection layer, a hole transport layer, a light-emitting layer, a hole blocking layer, an electron injection layer, and an electron transport layer, and not every one of these organic layers is required to exist. At least one of the hole injection layer, the hole transport layer, the hole blocking layer, the electron injection layer, the light-emitting layer, and the electron transport layer includes the platinum complex of the formula (I).

Preferably, a layer where the platinum complex of the formula (I) is located is a light-emitting layer or an electron transport layer.

The total thickness of the organic layers of the device of the present invention is 1-1,000 nm, preferably 1-500 nm, and more preferably 5-300 nm.

The organic layer can be formed into a thin film by an evaporation or solution method.

The series of binuclear platinum complex luminescent materials disclosed in the present invention show unexpected characteristics, significantly improve the luminous efficiency and device service life of the compound, and have good thermal stability, thus meeting requirements of OLED panels for luminescent materials.

### BRIEF DESCRIPTION OF DRAWINGS

FIG. 1 is a structural diagram of an organic light-emitting diode device of the present invention,

where 10 refers to a glass substrate, 20 refers to an anode, 30 refers to a hole injection layer, 40 refers to a hole transport layer, 50 refers to a light-emitting layer, 60 refers to an electron transport layer, 70 refers to an electron injection layer, and 80 refers to a cathode.

### DETAILED DESCRIPTION OF EMBODIMENTS

The present invention has no requirements for synthesis methods of materials. In order to describe the present invention in more detail, the following examples are provided, but the present invention is not limited to the examples. Unless otherwise specified, all raw materials used in the following synthesis processes are commercially available products.

### Example 1: Synthesis of a Compound 25

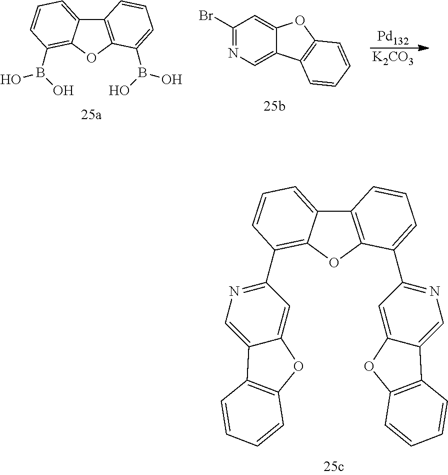

25a (2.0 g, 7.8 mmol), 25b (5.8 g, 23.4 mmol), Pd₁₃₂ (80 mg, 0.078 mmol), K₂CO₃ (3.32 g, 23.4 mmol), and toluene/ethanol/H₂O (40/30/20 ml) were put into a 250 ml three-mouth flask, and stirred for a reaction at 100° C. for 12 h under the protection of nitrogen. After the reaction was completed, most of a resulting reaction solution was spin-dried first, then deionized water was added, extraction was conducted with dichloromethane for three times, spin-drying was conducted, and treatment was conducted with a silica gel column (with a mixture of Hex and EA at a ratio of 10:1). Finally, 2.7 g of a brown solid was obtained. The yield was 69%.

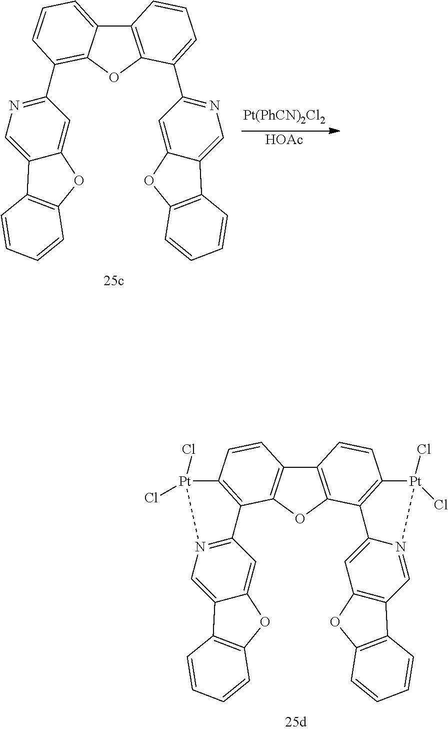

The 25c (1.81 g, 3.62 mmol), Pt(PhCN)₂Cl₂ (4.28 g, 9.06 mmol), and acetic acid (290 mL) were put into a 500 ml one-mouth flask, and subjected to a reaction at 135° C. for 48 h under the protection of nitrogen. After the reaction was completed, cooling was conducted to room temperature, and suction filtration was directly conducted. Then, a resulting solid was washed with methanol, and dried to obtain a black solid 25d.

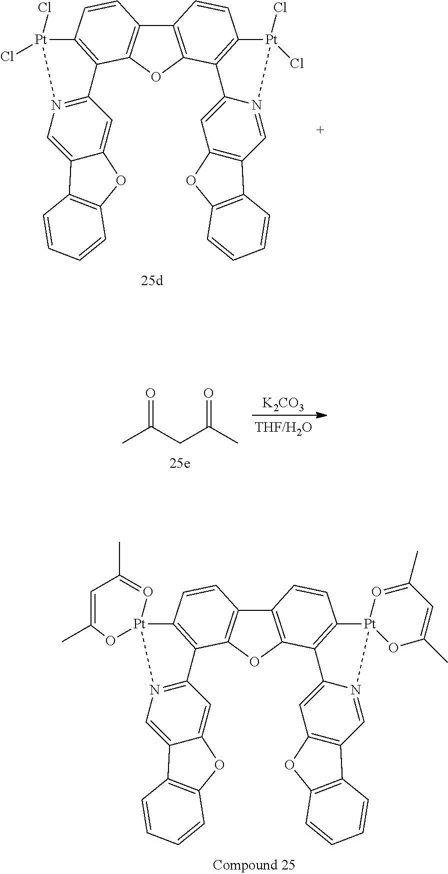

The 25d (4.0 g, 4.2 mmol), 25e (2.52 g, 25.21 mmol), K₂CO₃ (19.79 g), and tetrahydrofuran/H₂O (300/50 ml) were stirred for a reaction at 85° C. for 12 h under the protection of nitrogen. After the reaction was completed, most of a resulting reaction solution was spin-dried first, then deionized water was added, extraction was conducted with dichloromethane for three times, spin-drying was conducted, and treatment was conducted with a silica gel column (with a mixture of Hex and EA at a ratio of 20:1). Then, treatment was conducted with a silica gel column (with a mixture of Hex and DCM at a ratio of 2:1). Finally, 685 mg of a red solid compound 25 was obtained. The high-resolution mass spectrometry was: 1088.135 (compound 25).

### Example 2: Synthesis of a Compound 40

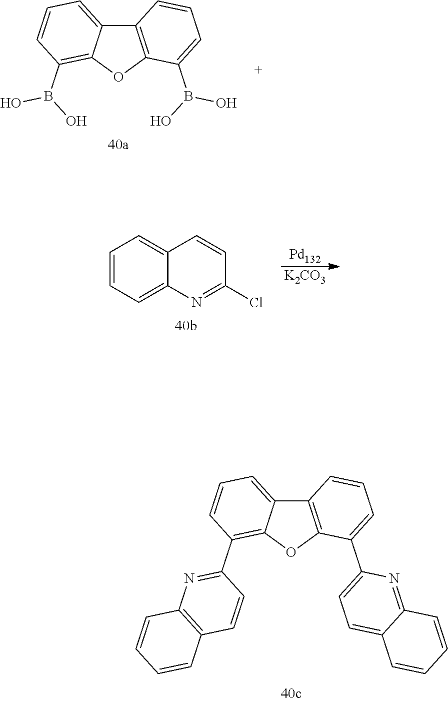

40a (2.0 g, 7.8 mmol), 40b (3.9 g, 23.4 mmol), Pd₁₃₂ (80 mg, 0.078 mmol), K₂CO₃ (3.32 g, 23.4 mmol), and toluene/ethanol/H₂O (40/30/20 ml) were put into a 250 ml three-mouth flask, and stirred for a reaction at 100° C. for 12 h under the protection of nitrogen. After the reaction was completed, most of a resulting reaction solution was spin-dried first, then deionized water was added, extraction was conducted with dichloromethane for three times, spin-drying was conducted, and treatment was conducted with a silica gel column (with a mixture of Hex and EA at a ratio of 10:1).

Finally, 3.0 g of a brown solid was obtained. The yield was 73%.

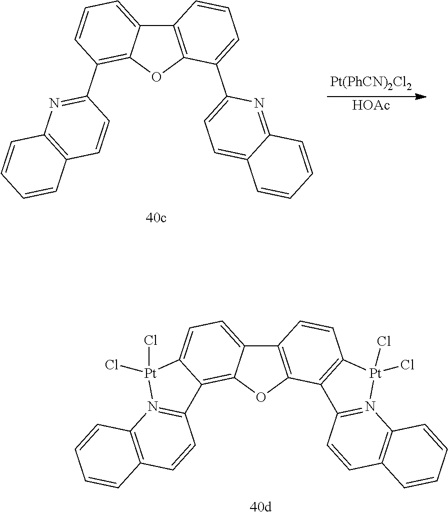

The 40c (1.53 g, 3.62 mmol), Pt(PhCN)₂Cl₂ (4.28 g, 9.06 mmol), and acetic acid (290 mL) were put into a 500 ml one-mouth flask, and subjected to a reaction at 135° C. for 48 h under the protection of nitrogen. After the reaction was completed, cooling was conducted to room temperature, and suction filtration was directly conducted. Then, a resulting solid was washed with methanol, and dried to obtain a black solid 40d.

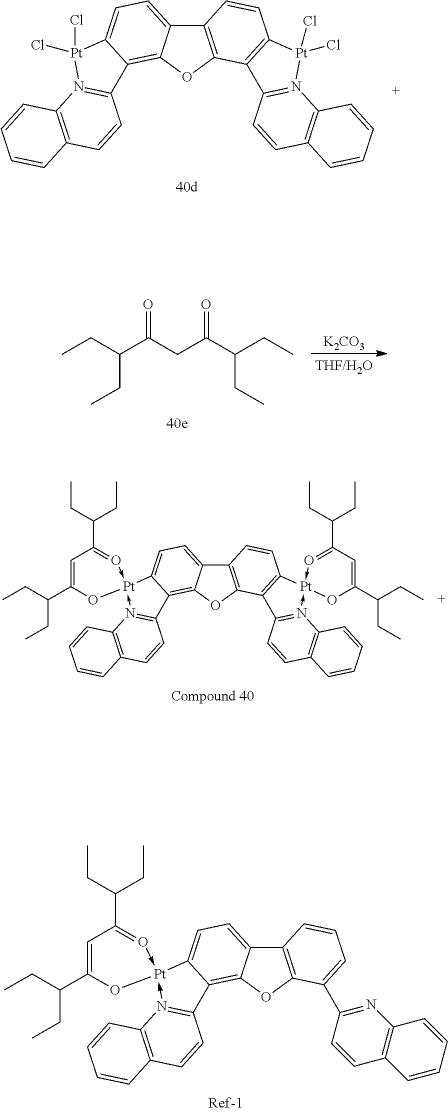

The 40d (4.0 g, 4.2 mmol), 40e (5.34 g, 25.21 mmol), K₂CO₃ (19.79 g), and tetrahydrofuran/H₂O (300/50 ml) were stirred for a reaction at 85° C. for 12 h under the protection of nitrogen. After the reaction was completed, most of a resulting reaction solution was spin-dried first, then deionized water was added, extraction was conducted with dichloromethane for three times, spin-drying was conducted, and treatment was conducted with a silica gel column (with a mixture of Hex and EA at a ratio of 20:1). Then, treatment was conducted with a silica gel column (with a mixture of Hex and DCM at a ratio of 2:1). Finally, 500 mg of a red solid compound 40 and 800 mg of a red solid compound Ref-1 were obtained.

The high-resolution mass spectrometry was as follows: 1132.395 (compound 40) and 827.873 (Ref-1).

### Example 3: Synthesis of a Compound 60

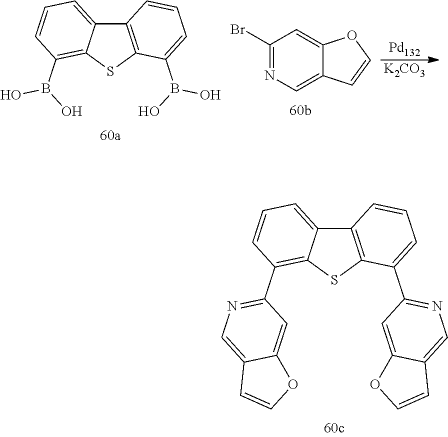

60a (2.12 g, 7.8 mmol), 60b (4.61 g, 23.4 mmol), Pd₁₃₂ (80 mg, 0.078 mmol), K₂CO₃ (3.32 g, 23.4 mmol), and toluene/ethanol/H₂O (40/30/20 ml) were put into a 250 ml three-mouth flask, and stirred for a reaction at 100° C. for 12 h under the protection of nitrogen. After the reaction was completed, most of a resulting reaction solution was spin-dried first, then deionized water was added, extraction was conducted with dichloromethane for three times, spin-drying was conducted, and treatment was conducted with a silica gel column (with a mixture of Hex and EA at a ratio of 10:1). Finally, 2.4 g of a brown solid was obtained. The yield was 75%.

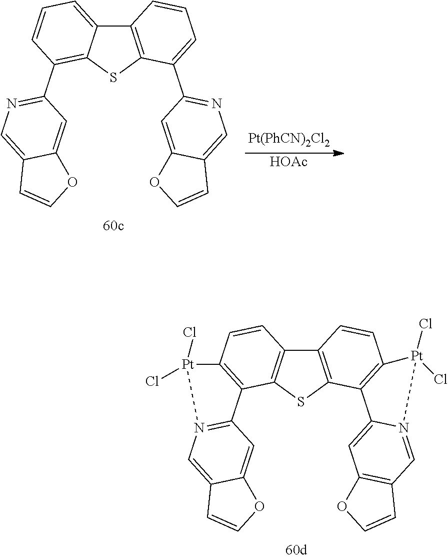

The 60c (1.51 g, 3.62 mmol), Pt(PhCN)₂Cl₂ (4.28 g, 9.06 mmol), and acetic acid (290 mL) were put into a 500 ml one-mouth flask, and subjected to a reaction at 135° C. for 48 h under the protection of nitrogen. After the reaction was completed, cooling was conducted to room temperature, and suction filtration was directly conducted. Then, a resulting solid was washed with methanol, and dried to obtain a black solid 60d.

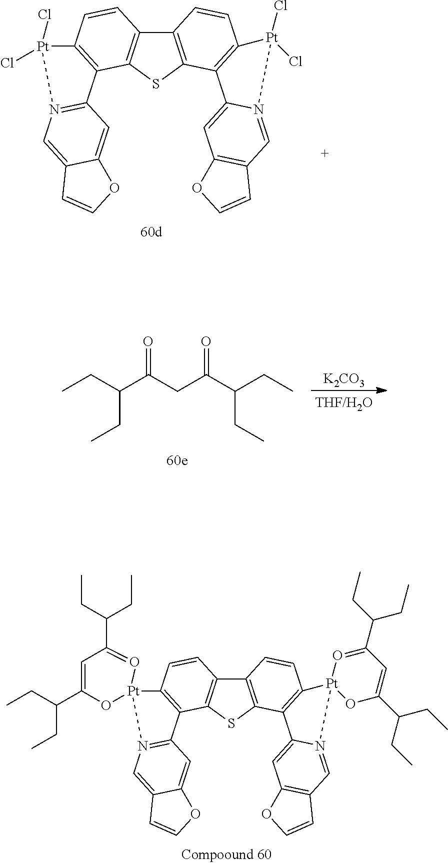

The 60d (3.97 g, 4.2 mmol), 60e (5.35 g, 25.21 mmol), K₂CO₃ (19.79 g), and tetrahydrofuran/H₂O (300/50 ml) were stirred for a reaction at 85° C. for 12 h under the protection of nitrogen. After the reaction was completed, most of a resulting reaction solution was spin-dried first, then deionized water was added, extraction was conducted with dichloromethane for three times, spin-drying was conducted, and treatment was conducted with a silica gel column (with a mixture of Hex and EA at a ratio of 20:1). Then, treatment was conducted with a silica gel column (with a mixture of Hex and DCM at a ratio of 2:1). Finally, 908 mg of a red solid compound 60 was obtained. The high-resolution mass spectrometry was: 1228.331 (compound 60).

### Example 4

### Synthesis of a Compound 80

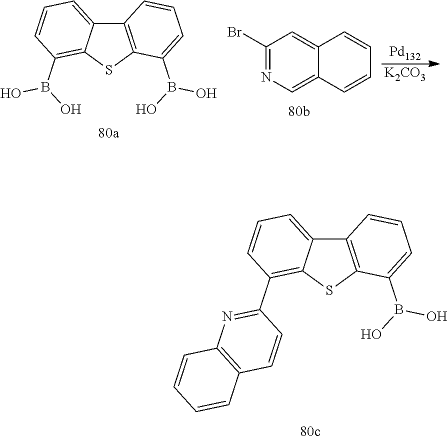

80a (2.12 g, 7.8 mmol), 80b (1.78 g, 8.58 mmol), Pd₁₃₂ (80 mg, 0.078 mmol), K₂CO₃ (3.32 g, 23.4 mmol), and toluene/ethanol/H₂O (40/30/20 ml) were put into a 250 ml three-mouth flask, and stirred for a reaction at 100° C. for 12 h under the protection of nitrogen. After the reaction was completed, most of a resulting reaction solution was spin-dried first, then deionized water was added, extraction was conducted with dichloromethane for three times, spin-drying was conducted, and treatment was conducted with a silica gel column (with a mixture of Hex and EA at a ratio of 10:1). Finally, 2.35 g of a light yellow solid was obtained. The yield was 85%.

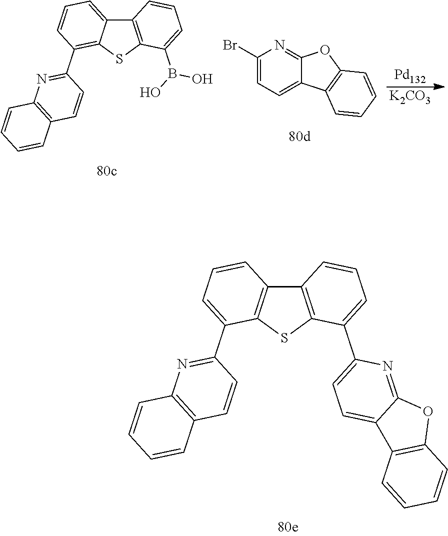

The 80c (2.35 g, 6.63 mmol), 80d (1.81 g, 7.29 mmol), Pd₁₃₂ (68 mg, 0.066 mmol), K₂CO₃ (2.83 g, 20.0 mmol), and toluene/ethanol/H₂O (40/30/20 ml) were put into a 250 ml three-mouth flask, and stirred for a reaction at 100° C. for 12 h under the protection of nitrogen. After the reaction was completed, most of a resulting reaction solution was spin-dried first, then deionized water was added, extraction was conducted with dichloromethane for three times, spin-drying was conducted, and treatment was conducted with a silica gel column (with a mixture of Hex and EA at a ratio of 10:1). Finally, 2.47 g of a yellow solid was obtained. The yield was 78%.

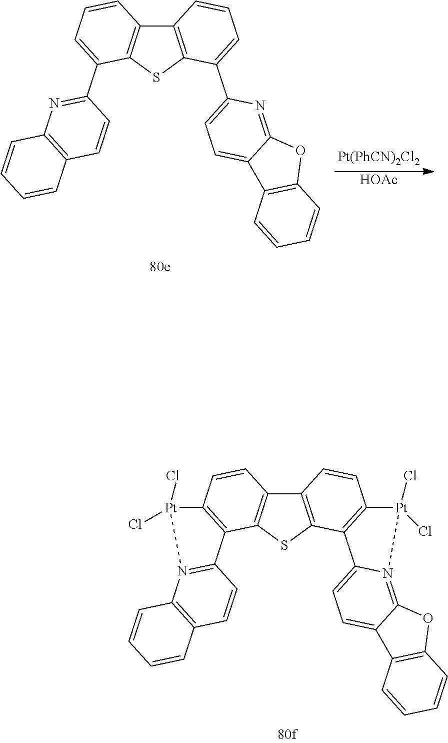

The 80e (1.73 g, 3.62 mmol), Pt(PhCN)₂Cl₂ (4.28 g, 9.06 mmol), and acetic acid (290 mL) were put into a 500 ml one-mouth flask, and subjected to a reaction at 135° C. for 48 h under the protection of nitrogen. After the reaction was completed, cooling was conducted to room temperature, and suction filtration was directly conducted. Then, a resulting solid was washed with methanol, and dried to obtain a black solid 80f.

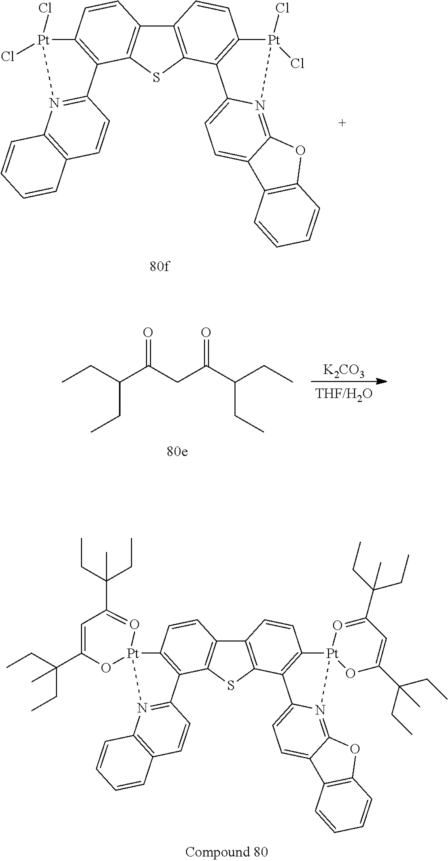

The 80f (4.22 g, 4.2 mmol), 80e (6.05 g, 25.21 mmol), K₂CO₃ (19.79 g), and tetrahydrofuran/H₂O (300/50 ml) were stirred for a reaction at 85° C. for 12 h under the protection of nitrogen. After the reaction was completed, most of a resulting reaction solution was spin-dried first, then deionized water was added, extraction was conducted with dichloromethane for three times, spin-drying was conducted, and treatment was conducted with a silica gel column (with a mixture of Hex and EA at a ratio of 20:1). Then, treatment was conducted with a silica gel column (with a mixture of Hex and DCM at a ratio of 2:1). Finally, 958 mg of a red solid compound 80 was obtained. The high-resolution mass spectrometry was: 1344.430 (compound 80).

### Example 5

### Synthesis of a Compound 83

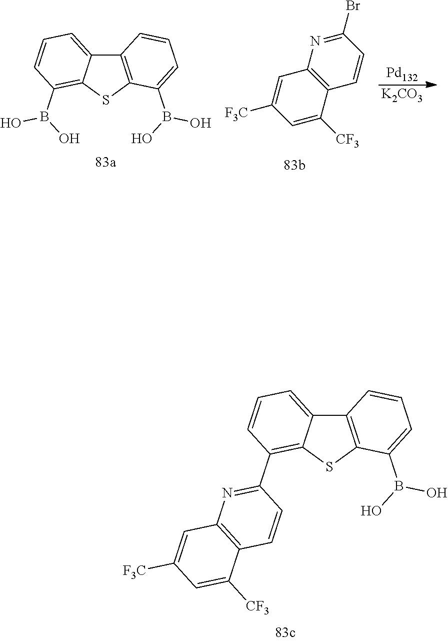

83a (2.12 g, 7.8 mmol), 83b (2.94 g, 8.58 mmol), Pd₁₃₂ (80 mg, 0.078 mmol), K₂CO₃ (3.32 g, 23.4 mmol), and toluene/ethanol/H₂O (40/30/20 ml) were put into a 250 ml three-mouth flask, and stirred for a reaction at 100° C. for 12 h under the protection of nitrogen. After the reaction was completed, most of a resulting reaction solution was spin-dried first, then deionized water was added, extraction was conducted with dichloromethane for three times, spin-drying was conducted, and treatment was conducted with a silica gel column (with a mixture of Hex and EA at a ratio of 10:1).

Finally, 3.10 g of a light yellow solid was obtained. The yield was 81%.

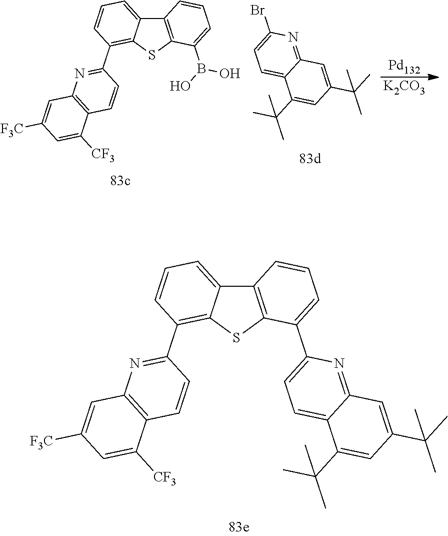

The 83c (3.10 g, 6.32 mmol), 83d (2.12 g, 6.95 mmol), Pd₁₃₂ (65 mg, 0.063 mmol), K₂CO₃ (2.69 g, 19.0 mmol), and toluene/ethanol /H₂O (40/30/20 ml) were put into a 250 ml three-mouth flask, and stirred for a reaction at 100° C. for 12 h under the protection of nitrogen. After the reaction was completed, most of a resulting reaction solution was spin-dried first, then deionized water was added, extraction was conducted with dichloromethane for three times, spin-drying was conducted, and treatment was conducted with a silica gel column (with a mixture of Hex and EA at a ratio of 10:1). Finally, 3.25 g of a yellow solid was obtained. The yield was 75%.

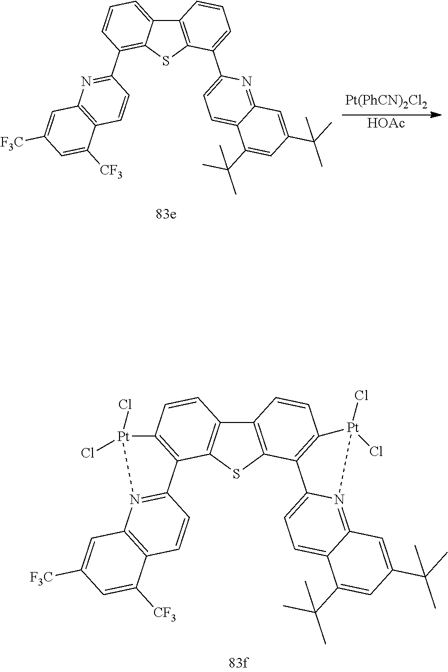

The 83e (2.48 g, 3.62 mmol), Pt(PhCN)₂Cl₂ (4.28 g, 9.06 mmol), and acetic acid (290 mL) were put into a 500 ml one-mouth flask, and subjected to a reaction at 135° C. for 48 h under the protection of nitrogen. After the reaction was completed, cooling was conducted to room temperature, and suction filtration was directly conducted. Then, a resulting solid was washed with methanol, and dried to obtain a black solid 83f.

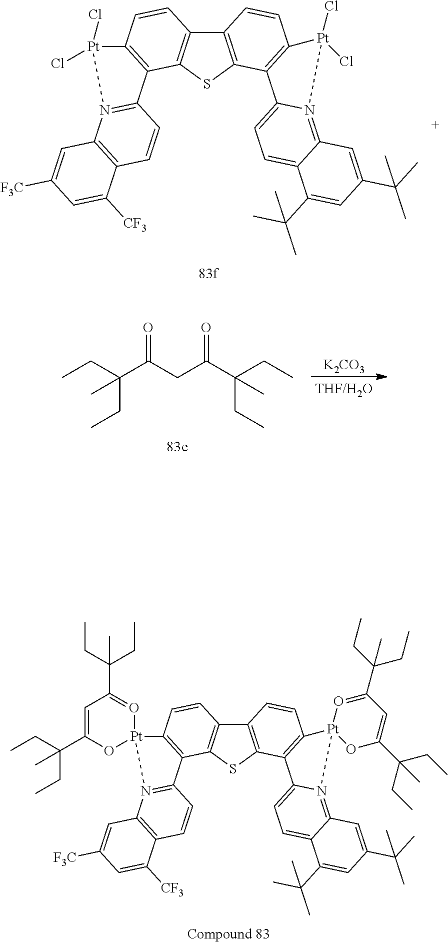

The 83f (5.10 g, 4.2 mmol), 83e (6.05 g, 25.21 mmol), K₂CO₃ (19.79 g), and tetrahydrofuran/H₂O (300/50 ml) were stirred for a reaction at 85° C. for 12 h under the protection of nitrogen. After the reaction was completed, most of a resulting reaction solution was spin-dried first, then deionized water was added, extraction was conducted with dichloromethane for three times, spin-drying was conducted, and treatment was conducted with a silica gel column (with a mixture of Hex and EA at a ratio of 20:1). Then, treatment was conducted with a silica gel column (with a mixture of Hex and DCM at a ratio of 2:1). Finally, 913 mg of a red solid compound 83 was obtained. The high-resolution mass spectrometry was: 1552.535 (compound 83).

A person skilled in the art shall know that the above-mentioned preparation methods are merely exemplary examples, and improvements on the examples can be made by a person skilled in the art to obtain other compound structures of the present invention.

### Examples 6-10

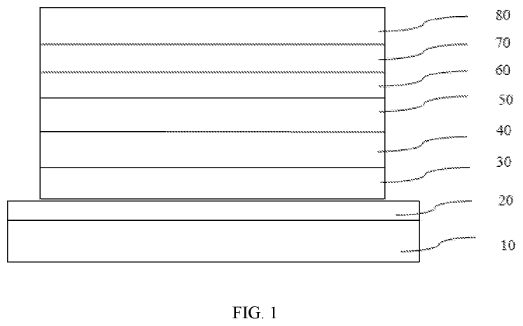

An organic light-emitting diode was prepared by using the complex luminescent material of the present invention. The structure of the device is as shown in FIG. 1.

First, a transparent conductive ITO glass substrate 10 (with an anode 20 on the surface) was sequentially washed with a detergent solution, deionized water, ethanol, acetone and deionized water, and then treated with oxygen plasma for 30 s.

Then, HATCN was evaporated on the ITO to serve as a hole injection layer 30 having a thickness of 10 nm.

Then, an HT compound was evaporated to form a hole transport layer 40 having a thickness of 40 nm.

Then, a light-emitting layer 50 having a thickness of 20 nm was evaporated on the hole transport layer, where the light-emitting layer was obtained by mixing and doping a platinum complex (20%) and CBP(80%) (the corresponding platinum complex in Examples 6-10 was compound 25, compound 40, compound 60, compound 80, and compound 83, respectively).

Then, AlQ₃ was evaporated on the light-emitting layer to serve as an electron transport layer 60 having a thickness of 40 nm.

Finally, LiF was evaporated to serve as an electron injection layer 70 having a thickness of 1 nm, and Al was evaporated to serve as a device cathode 80 having a thickness of 100 nm.

### Comparative Example 1

A device of Comparative Example 1 was prepared by replacing the platinum complex in the above examples with a compound Ref-1 based on the same preparation method.

Structural formulas of HATCN, HT, CBP, A1Q3, and Ref-1 in the device are as follows:

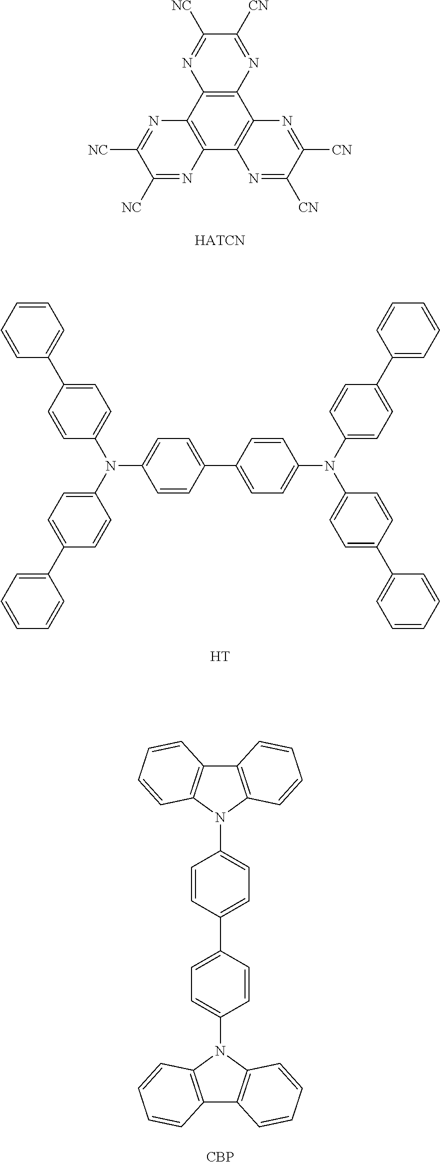

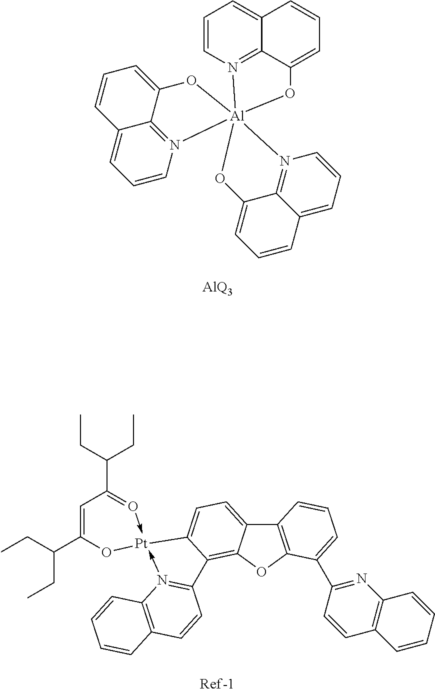

Device properties of organic electroluminescent devices in Examples 6-10 and Comparative Example 1 at a current density of 20 mA/cm² are listed in Table 1.

TABLE 1

| Device | | Driving | Luminous | Device service |
|---|---|---|---|---|
| number | Complex | voltage | efficiency | life (LT95) |
| Comparative | Ref-1 | 1 | 1 | 1 |
| Example 1 | | | | |
| Example 6 | Compound 25 | 0.88 | 1.21 | 2.39 |
| Example 7 | Compound 40 | 0.85 | 1.22 | 2.36 |
| Example 8 | Compound 60 | 0.89 | 1.18 | 2.35 |
| Example 9 | Compound 80 | 0.92 | 1.15 | 2.29 |
| Example 10 | Compound 83 | 0.92 | 1.17 | 2.31 |

Note:
Properties of the devices are tested on the basis of Example 1, and each index is set as 1; and LT95 indicates the corresponding time when the brightness of a device is reduced to 95% of the initial brightness (3,000 cd/m²).

According to the data in Table 1, it can be seen that under the same conditions, the platinum complex material of the present invention has lower driving voltage and higher luminous efficiency when applied to an organic light-emitting diode. In addition, the organic light-emitting diode based on the complex of the present invention has significantly better device service life than that based on the complex material in the comparative example, requirements of the display industry for luminescent materials can be met, and a good industrialization prospect is achieved.

The various embodiments described above are merely used as examples, and are not intended to limit the scope of the present invention. On the premise of not departing from the spirit of the present invention, a variety of materials and structures in the present invention can be replaced with other materials and structures. It shall be understood that many modifications and changes can be made by a person skilled in the art without creative effort according to the concept of the present invention. Therefore, all technical solutions that can be obtained by a person skilled in the art through analysis, reasoning or partial research on the basis of the prior art shall fall within the protection scope as defined by the claims.

1. A binuclear metal platinum complex, being a compound having a structure of a formula (I):
(I)
wherein
each of R¹ to R⁵ is independently selected from hydrogen, deuterium, halogen, amino, carbonyl, carboxyl, thioalkyl, cyano, trimethylsilyl, sulfonyl, phosphino, substituted or unsubstituted alkyl containing 1-20 carbon atoms, substituted or unsubstituted cycloalkyl containing 3-20 ring carbon atoms, substituted or unsubstituted alkenyl containing 2-20 carbon atoms, substituted or unsubstituted alkoxyl containing 1-20 carbon atoms, substituted or unsubstituted aryl containing 6-30 carbon atoms, and substituted or unsubstituted heteroaryl containing 3-30 carbon atoms, or any two adjacent substituents are connected or fused to form a ring, and the heteroaryl comprises one or more of N, S, and O heteroatoms;
each of A and B is independently selected from N-containing heteroaromatic rings containing 7-24 carbon atoms; the N-containing heteroaromatic rings comprise or do not comprise an S or O heteroatom;
the “substituted” refers to substitution with halogen, amino, cyano, phenyl, or C₁-C₄ alkyl;
m or n is independently 0 to 4;
and X is O or S.

2. The binuclear metal platinum complex according to claim 1, wherein each of the R¹ to R⁵ is independently selected from hydrogen, deuterium, halogen, amino, carbonyl, carboxyl, cyano, trimethylsilyl, substituted or unsubstituted alkyl containing 1-6 carbon atoms, substituted or unsubstituted cycloalkyl containing 3-6 ring carbon atoms, substituted or unsubstituted alkenyl containing 2-6 carbon atoms, substituted or unsubstituted alkoxyl containing 1-6 carbon atoms, substituted or unsubstituted aryl containing 6-12 carbon atoms, and substituted or unsubstituted heteroaryl containing 3-6 carbon atoms, or any two adjacent substituents are connected or fused to form a ring, and the heteroaryl comprises one or more of N, S, and O heteroatoms;
and the A and the B are a same N-containing heteroaromatic ring.

3. The binuclear metal platinum complex according to claim 2, wherein each of the R¹ to R⁵ is independently selected from hydrogen, deuterium, halogen, substituted or unsubstituted C₁-C₆ alkyl, cyano, substituted or unsubstituted cycloalkyl containing 3-6 ring carbon atoms, substituted or unsubstituted aryl containing 6-12 carbon atoms, and substituted or unsubstituted heteroaryl containing 3-6 carbon atoms; the “substituted” refers to substitution with halogen or C₁-C₄ alkyl;
and the A and the B are an N-containing heteroaromatic ring having one of the following structures:

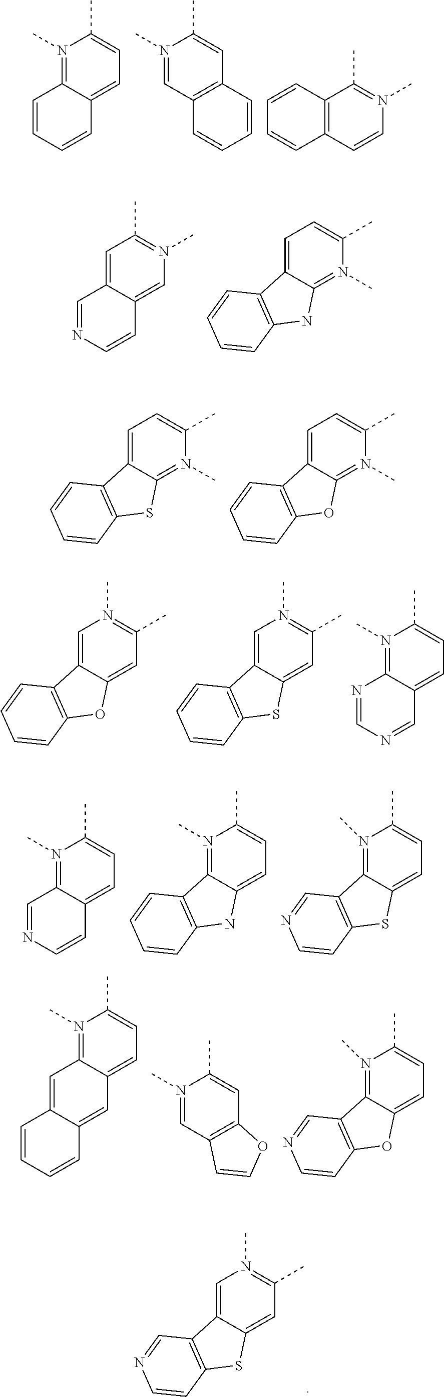

4. The binuclear metal platinum complex according to claim 3, wherein each of R₁ to R₂ is independently selected from hydrogen, deuterium, halogen, substituted or unsubstituted C₁-C₆ alkyl, cyano, substituted or unsubstituted cycloalkyl containing 3-6 ring carbon atoms, and substituted or unsubstituted aryl containing 6-12 carbon atoms; each of R₃ to R₅ is independently selected from hydrogen, deuterium, C₁-C₆ alkyl, and substituted or unsubstituted cycloalkyl containing 3-6 ring carbon atoms; and the “substituted” refers to substitution with a fluorine atom or C₁-C₄ alkyl.

5. The binuclear metal platinum complex according to claim 4, wherein each of the R₁ to R₂ is independently selected from hydrogen, deuterium, methyl, ethyl, isopropyl, isobutyl, tert-butyl, 3-substituted pentyl, cyano, substituted or unsubstituted cyclopentyl, substituted or unsubstituted cyclohexyl, and substituted or unsubstituted phenyl; and each of the R₃ to R₅ is independently selected from hydrogen, deuterium, methyl, ethyl, isopropyl, isobutyl, tert-butyl, pentyl, 3-substituted pentyl, and cyano.

6. The binuclear metal platinum complex according to any one of claims 1-5, wherein the R¹ and the R² are the same and have same substitution positions, and the m is equal to the n.

7. The binuclear metal platinum complex according to claim 6, wherein in the general formula (I), R⁴ is hydrogen.

8. The binuclear metal platinum complex according to claim 1, being one of the following compounds:

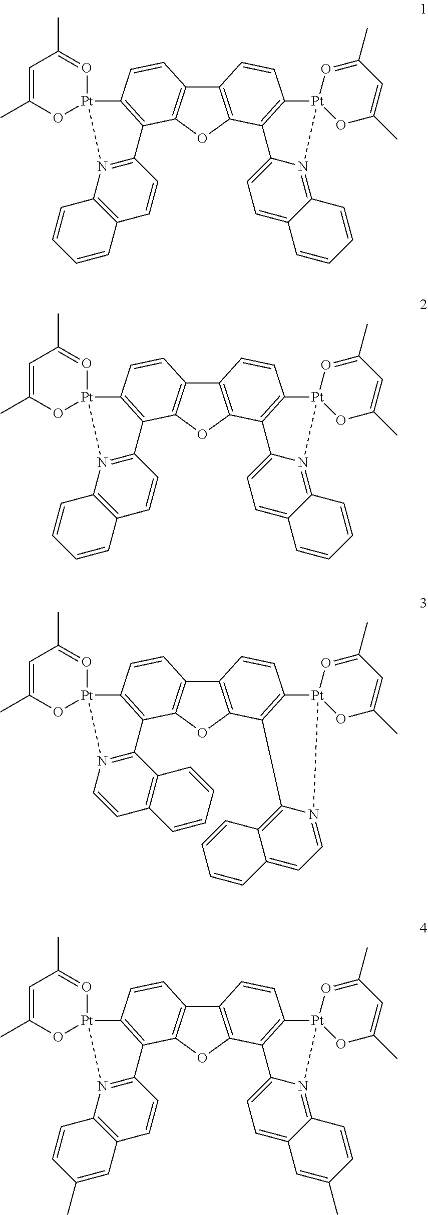

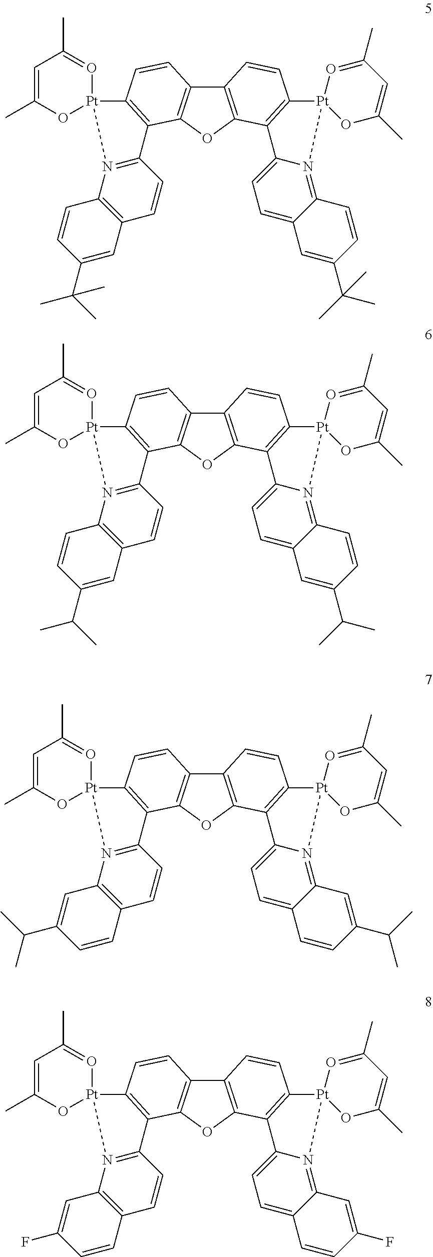

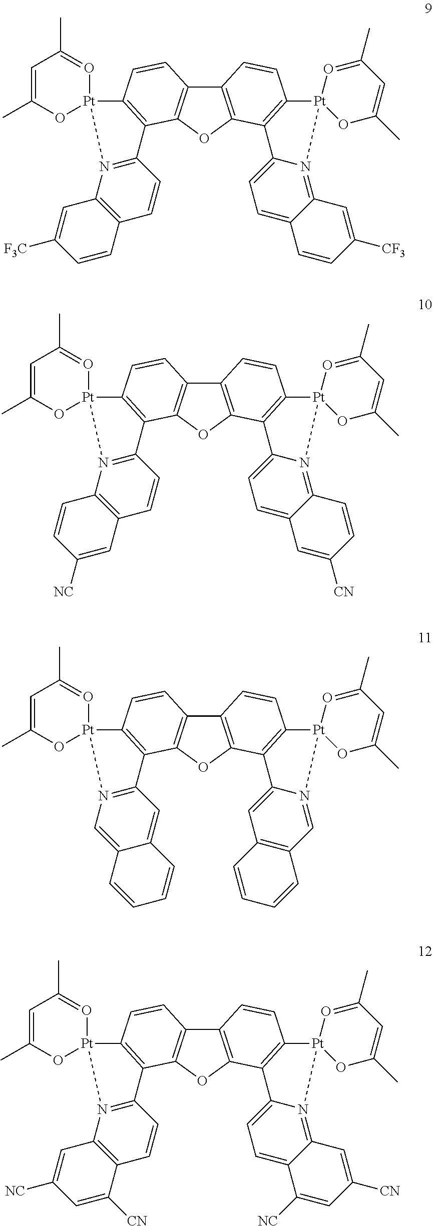

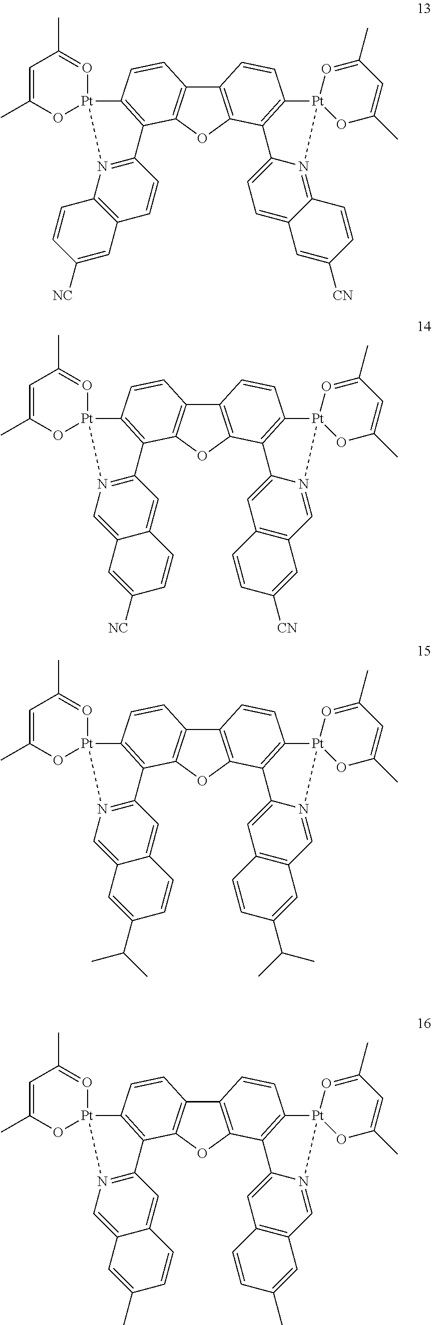

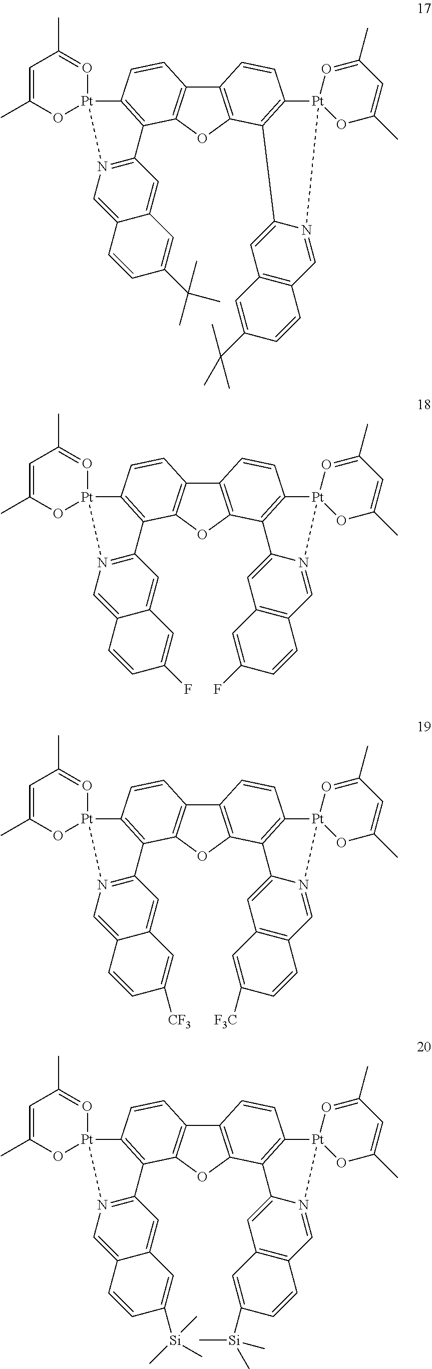

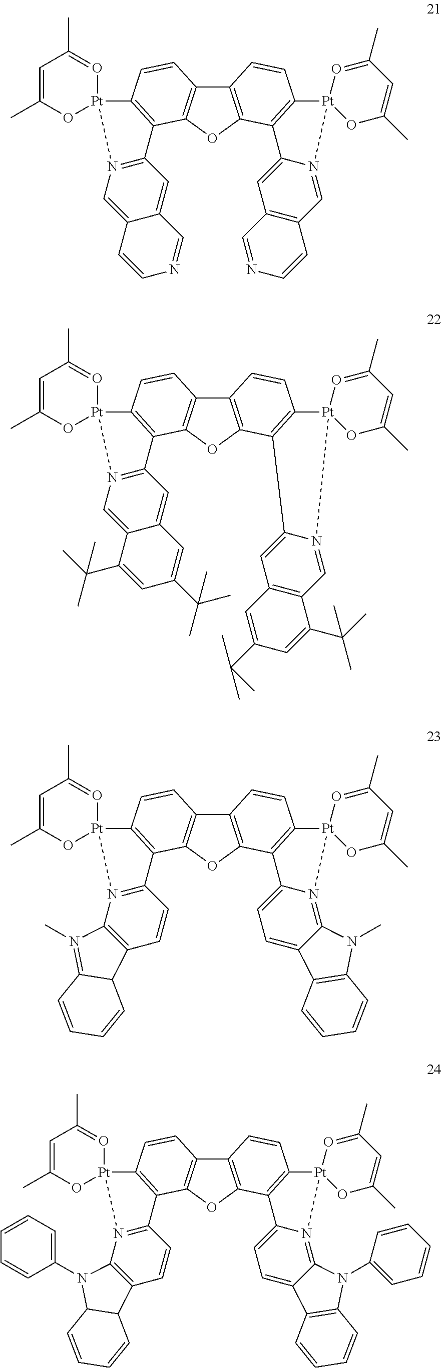

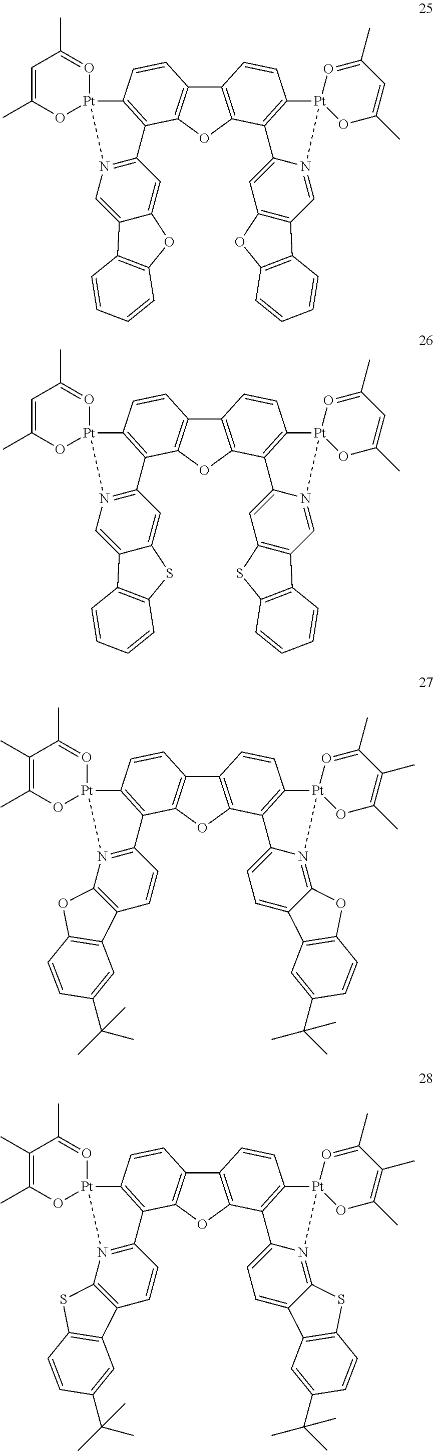

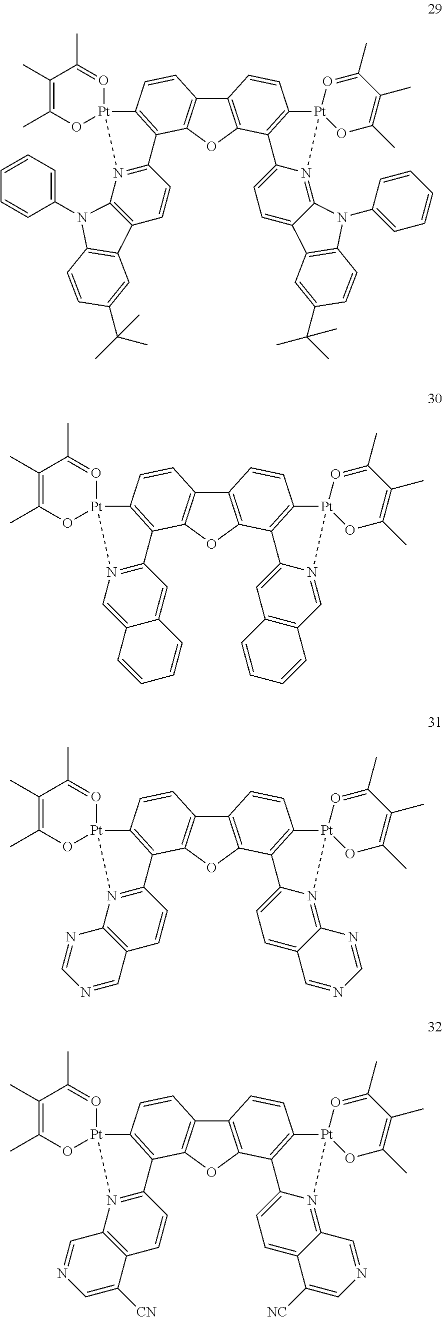

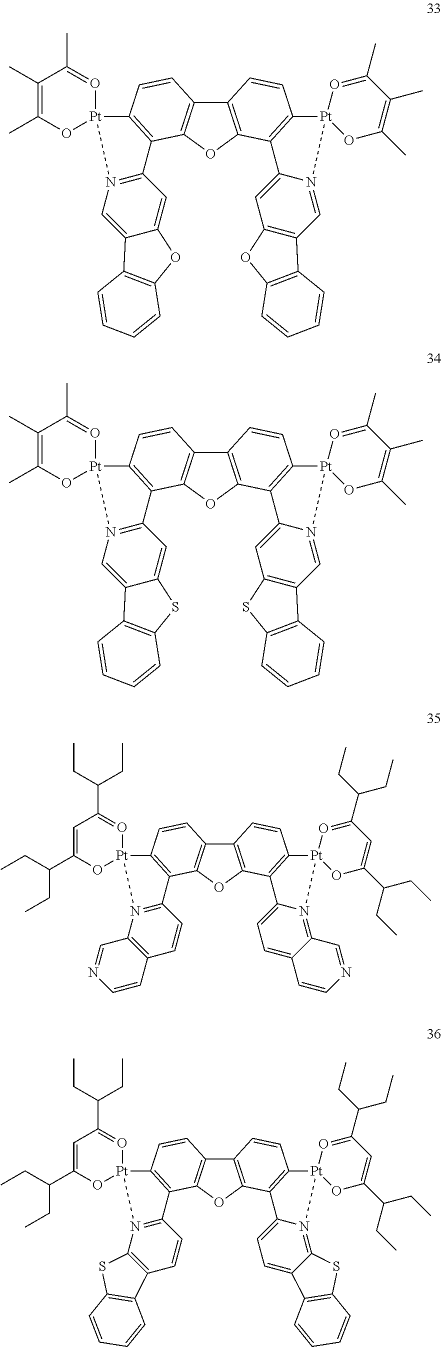

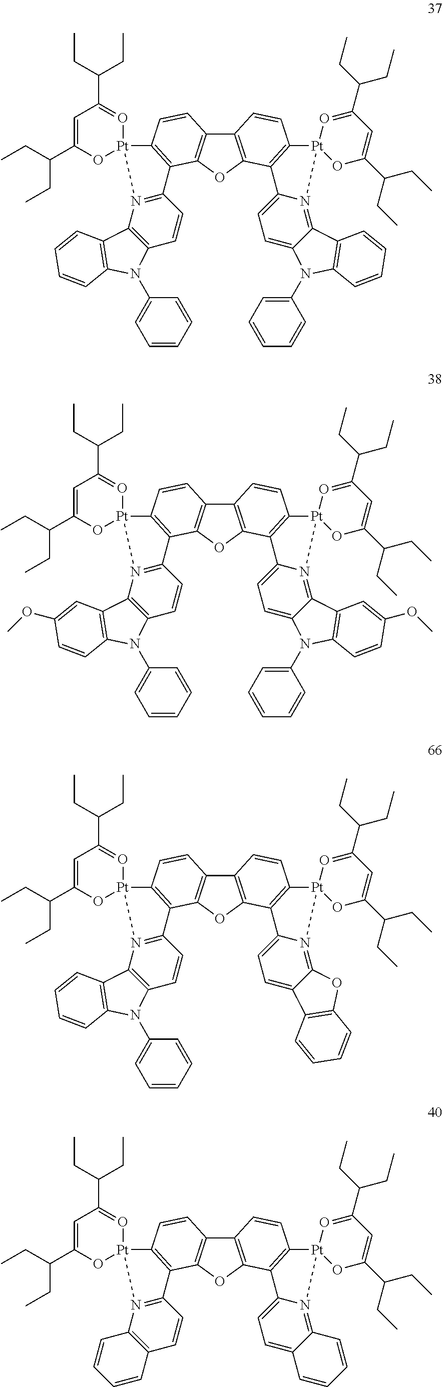

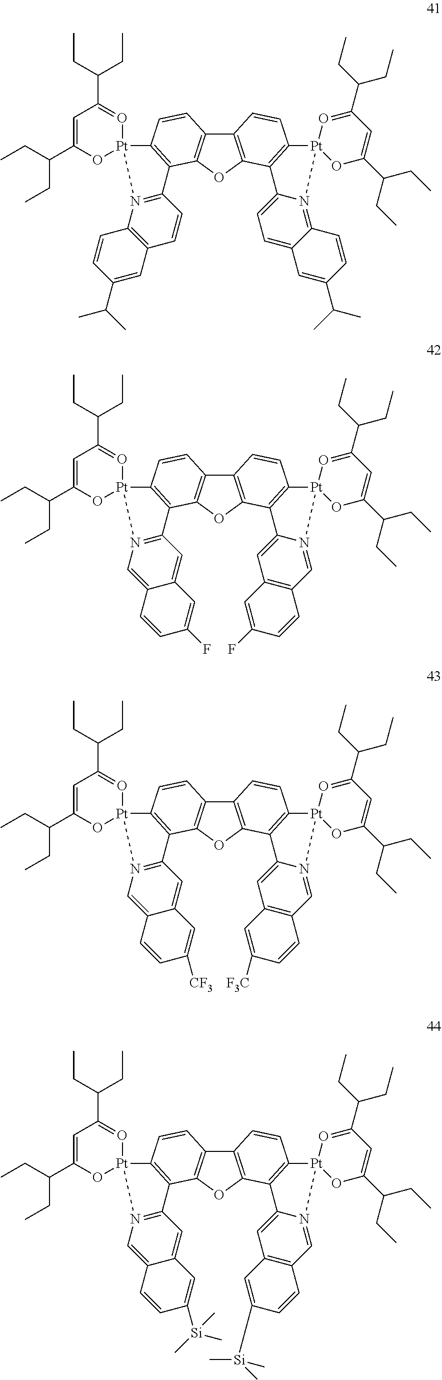

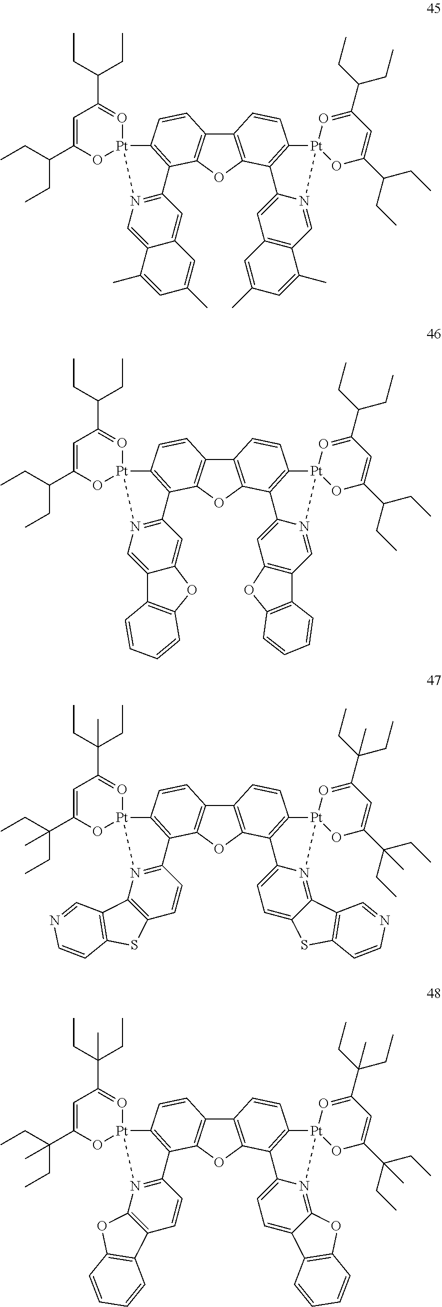

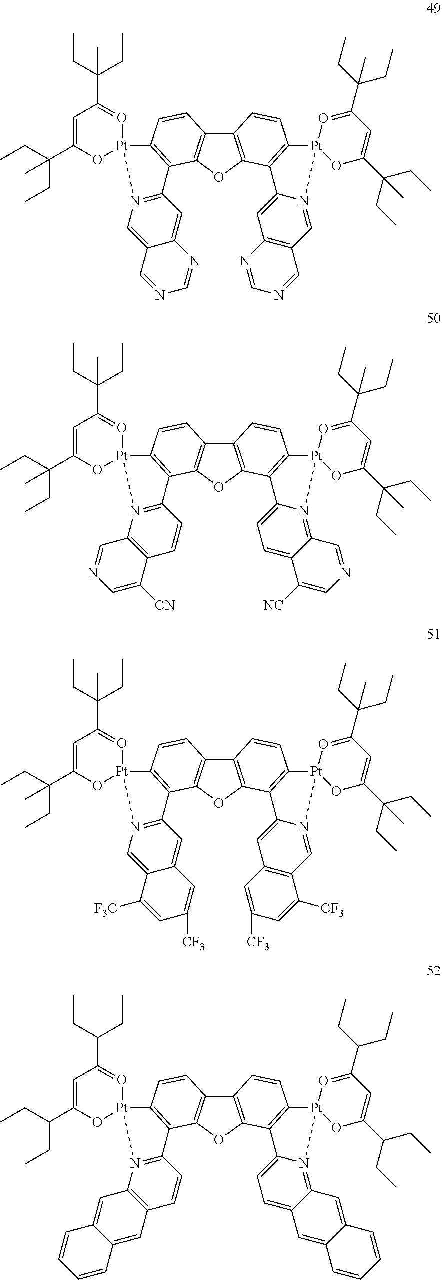

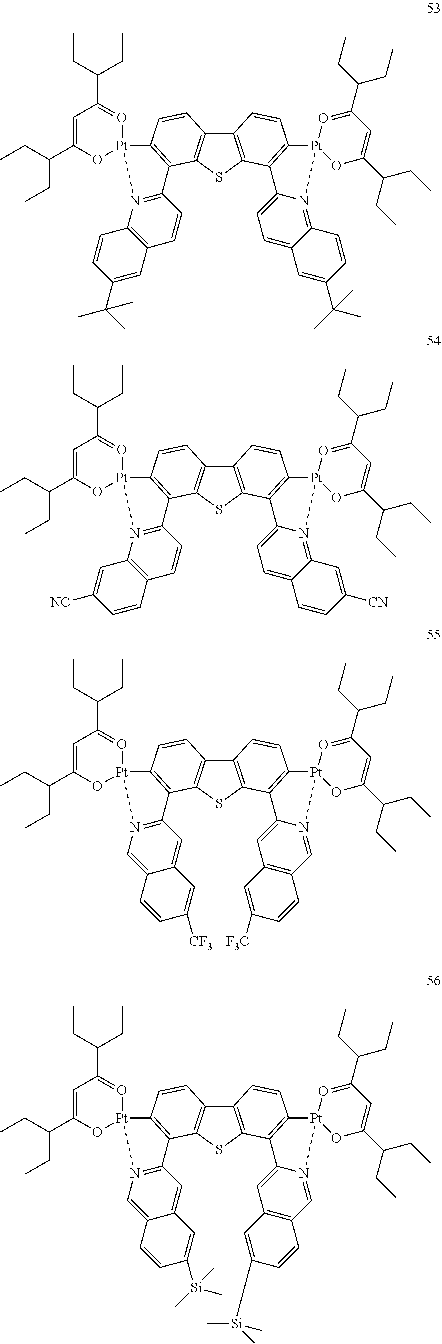

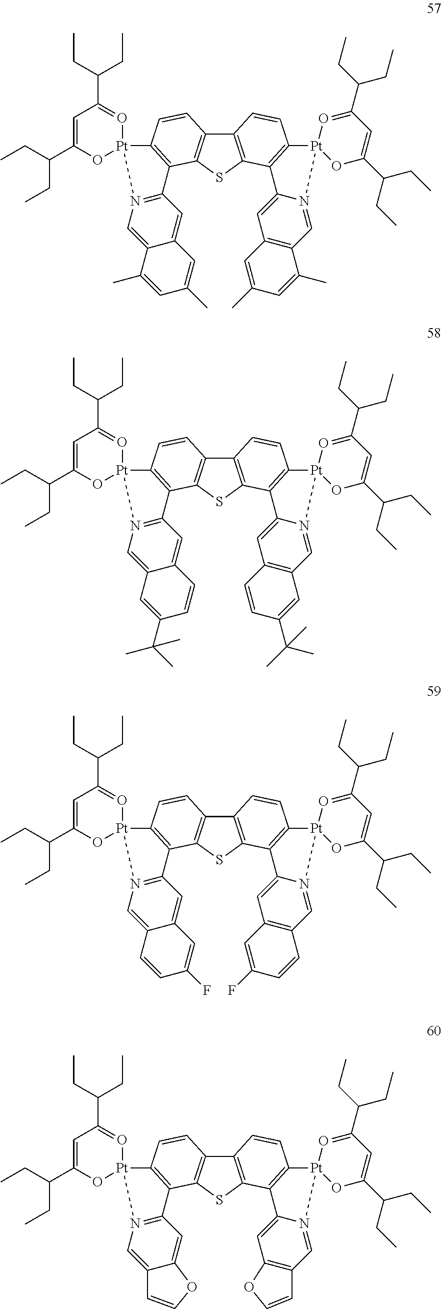

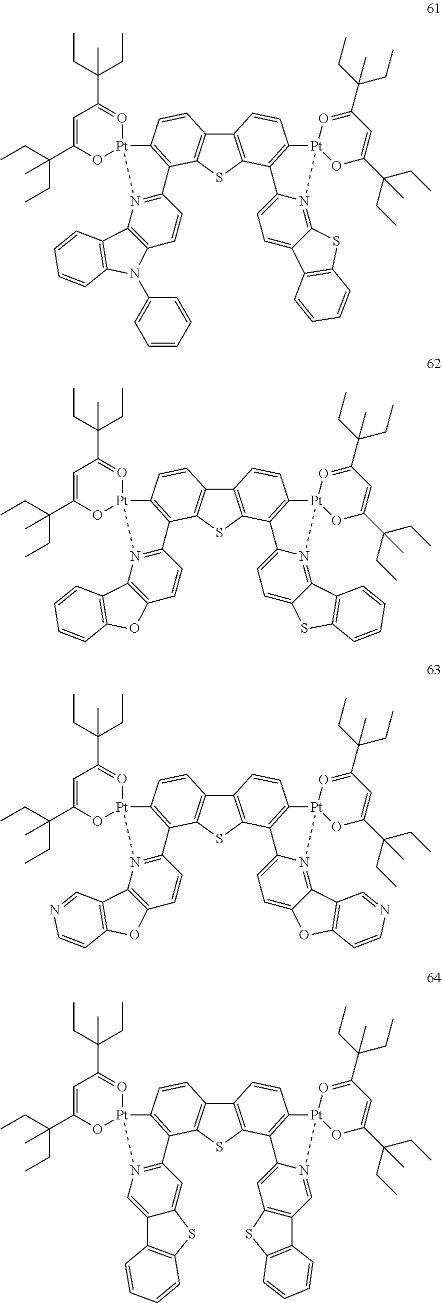

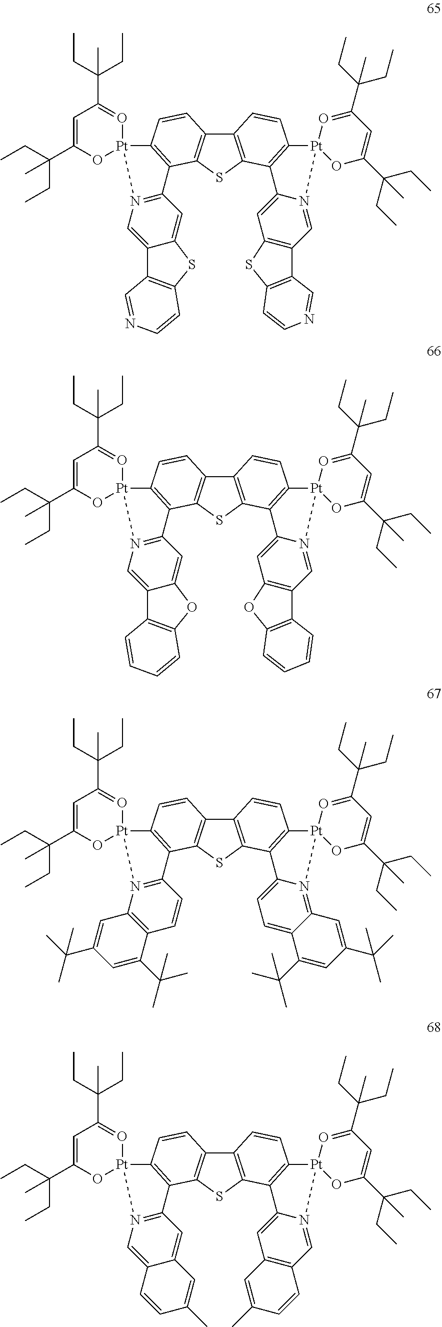

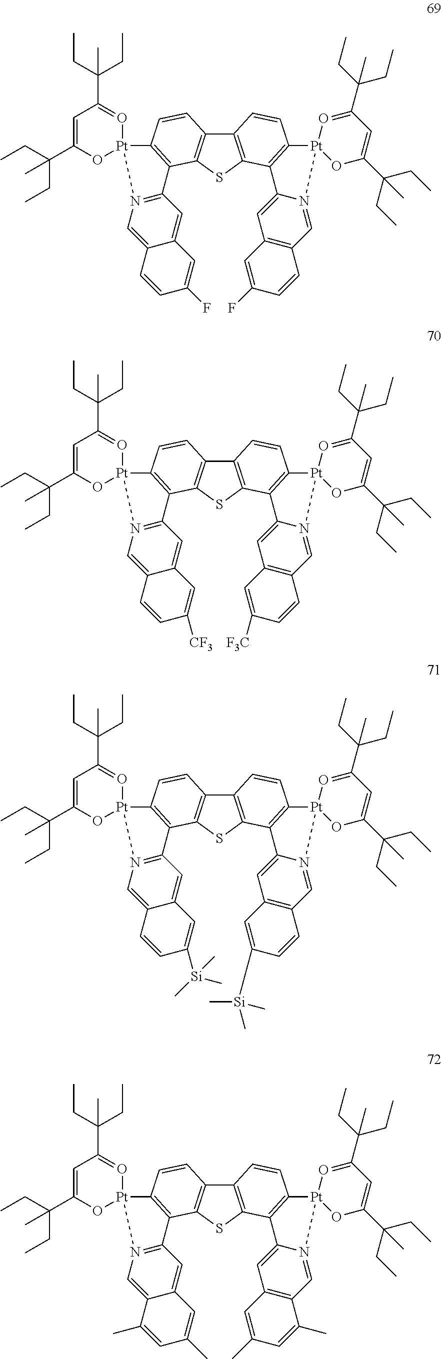

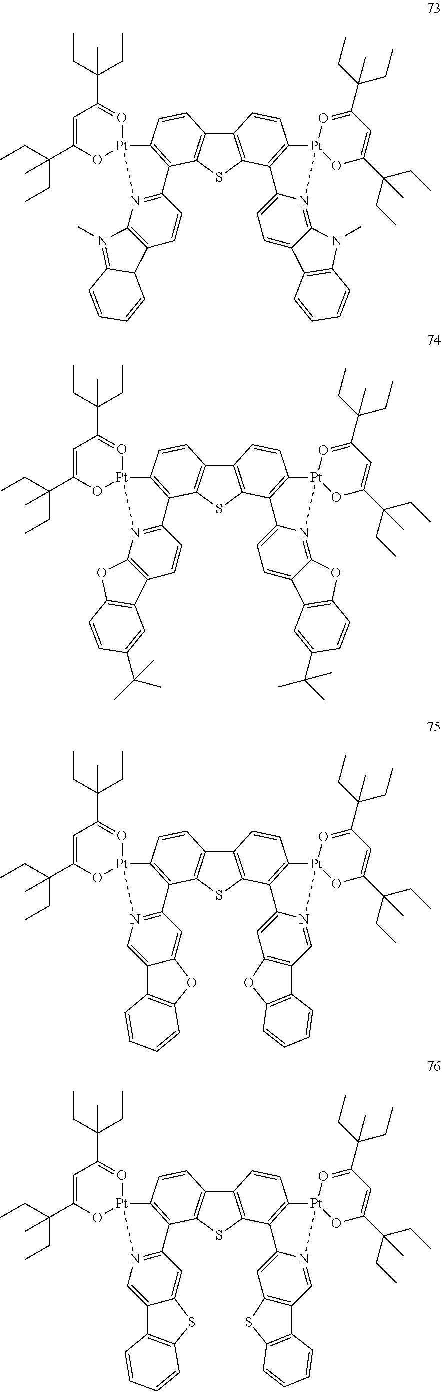

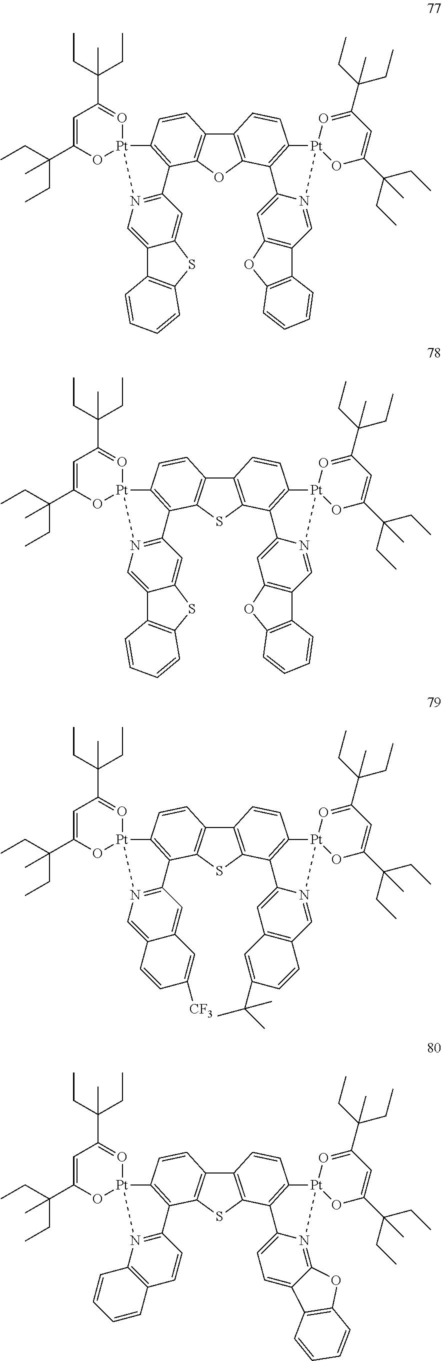

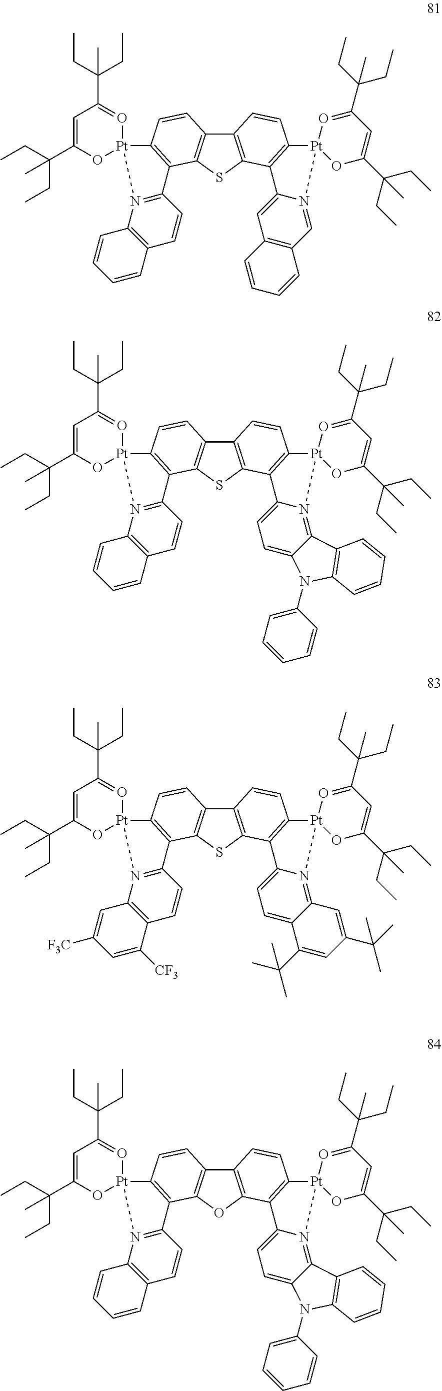

9. A precursor, namely ligand, of the binuclear metal platinum complex according to any one of claims 1-8, having the following structural formula:

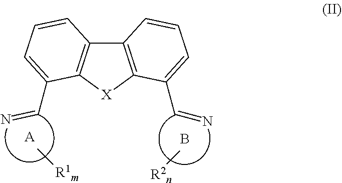

10. Application of the binuclear metal platinum complex according to any one of claims 1-8 in organic light-emitting diodes, organic thin film transistors, organic photovoltaic devices, light-emitting electrochemical cells, or chemical sensors

11. An organic light-emitting diode, comprising a cathode, an anode, and an organic layer, wherein the organic layer is one or more of a hole injection layer, a hole transport layer, a light-emitting layer, a hole blocking layer, an electron injection layer, and an electron transport layer, and the organic layer comprises the binuclear metal platinum complex according to any one of claims 1-8.

12. The organic light-emitting diode according to claim 11, wherein a layer where the binuclear metal platinum complex according to any one of claims 1-8 is located is a light-emitting layer.
